(19) United States
(12) Patent Application Publication
(10) Pub. No.: US 2024/0341141 A1
(43) Pub. Date: Oct. 10, 2024

(54) DISPLAY DEVICE

(71) Applicant: Samsung Display Co., LTD., Yongin-si (KR)

(72) Inventors: Jung Suk BANG, Yongin-si (KR); Sun Kwun SON, Yongin-si (KR); Dong Hee SHIN, Yongin-si (KR); Dong Il YOO, Yongin-si (KR); Myung Hun LIM, Yongin-si (KR)

(21) Appl. No.: 18/620,890

(22) Filed: Mar. 28, 2024

(30) Foreign Application Priority Data
Apr. 6, 2023 (KR) 10-2023-0045152

(51) Int. Cl. H10K 59/131; H10K 59/121

(52) U.S. Cl. CPC H10K 59/131; H10K 59/1213; H10K 59/1216

(57) ABSTRACT

A display device includes: a first pixel and a second pixel, including: a first transistor comprising a first active region, a first drain electrode, and a first source electrode respectively on one side and another side of the first active region, and a first gate electrode overlapping the first active region, a first capacitor electrode connected to the first gate electrode and overlapping the first source electrode, and a light emitting element connected to the first transistor, wherein a first end of the first source electrode of the first pixel, and a second end of the first source electrode of the second pixel face each other, a third end of the first capacitor electrode of the first pixel, and a fourth end of the first capacitor electrode of the second pixel face each other, and the first end is between the third end and the fourth end.

### CROSS-REFERENCE TO RELATED APPLICATION

The present application claims priority to and the benefit of Korean Patent Application No. 10-2023-0045152 filed on Apr. 6, 2023, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

The importance of display devices has steadily increased with the development of multimedia technology. Accordingly, various types of display devices such as a liquid crystal display (LCD) device, an organic light emitting diode (OLED) display device and the like have been developed.

Among display devices, a self-light emitting display device includes a self-light emitting element such as an organic light emitting element. The self-light emitting element may include two opposite electrodes and a light emitting layer interposed therebetween. In the case of using the organic light emitting element as the self-light emitting element, the electrons and holes from the two electrodes are recombined in the light emitting layer to produce excitons, which transition from the excited state to the ground state, for emitting light.

The self-light emitting display device is attracting attention as a next-generation display device because of being able to meet the high display quality requirements such as wide viewing angle, high brightness and contrast, and quick response speed as well as having relatively low power consumption, being relatively lightweight, and being relatively thin due to having relatively fewer components that consume power such as a backlight unit.

The above information disclosed in this Background section is only for enhancement of understanding of the background and therefore the information discussed in this Background section does not necessarily constitute prior art.

### SUMMARY

Aspects of some embodiments of the present disclosure include a display device in which a node connected to a gate electrode of one pixel and a node connected to a gate electrode of another pixel are adjacent to each other, such that a coupling phenomenon in which the voltage is applied to the gate electrode of one pixel by the voltage applied to the gate electrode of another pixel is relatively reduced or minimized.

Aspects of some embodiments of the present disclosure also include a display device in which a node connected to a pixel electrode of one pixel overlaps a node connected to a gate electrode of another pixel, such that a coupling phenomenon in which the voltage is applied to the pixel electrode of one pixel by the voltage applied to the pixel electrode of another pixel is relatively reduced or minimized.

Aspects of the present disclosure also provide a display device in which an edge discoloration in which a color other than white or black is displayed at a boundary between white and black is minimized.

However, aspects of embodiments according to the present disclosure are not restricted to those set forth herein. The above and other aspects of embodiments according to the present disclosure will become more apparent to one of ordinary skill in the art to which the present disclosure pertains by referencing the detailed description of the present disclosure given below.

According to some embodiments of the present disclosure, a display device includes, a first pixel and a second pixel, each including, a first transistor including a first active region, a first drain electrode and a first source electrode respectively on one side and the other side of the first active region, and a first gate electrode overlapping the first active region, a first capacitor electrode connected to the first gate electrode and overlapping the first source electrode, and a light emitting element connected to the first transistor, wherein a first end that is one end of the first source electrode of the first pixel, and a second end that is one end of the first source electrode of the second pixel face each other, a third end that is one end of the first capacitor electrode of the first pixel, and a fourth end that is one end of the first capacitor electrode of the second pixel face each other, and the first end is between the third end and the fourth end.

According to some embodiments, the second end is between the third end and the fourth end.

According to some embodiments, a distance between the first end and the second end is smaller than a distance between the second end and the third end.

According to some embodiments, a distance between the first end and the second end is smaller than a distance between the first end and the fourth end.

According to some embodiments, a distance between the third end and the fourth end is greater than a distance between the first end and the second end.

According to some embodiments, the display device further comprising a first voltage line connected to the first drain electrode of the first pixel, wherein the first voltage line comprises a main portion and a protrusion portion protruding from the main portion, and the protrusion portion is between the first end and the second end.

According to some embodiments, the display device further comprising a shielding electrode connected to the first voltage line, wherein the shielding electrode is between the first end and the second end.

According to some embodiments, the light emitting element of the second pixel comprises a first electrode, a light emitting layer on the first electrode, and a second electrode on the light emitting layer, and the first to fourth ends overlap the first electrode of the second pixel.

According to some embodiments, the first electrode of the second pixel overlaps the first source electrode of the first pixel.

According to some embodiments, the first electrode of the second pixel overlaps the first capacitor electrode of the first pixel.

According to some embodiments, the first capacitor electrode of the first pixel and the first capacitor electrode of the second pixel are adjacent to each other.

According to some embodiments of the present disclosure, a display device includes, a first pixel and a second pixel, each comprising, a first transistor comprising a first active region, a first drain electrode and a first source electrode respectively on one side and the other side of the first active region, and a first gate electrode overlapping the first active region, a first capacitor electrode connected to the first gate electrode and overlapping the first source electrode, and a light emitting element connected to the first transistor and comprising a first electrode, a light emitting layer on the first electrode, and a second electrode on the light emitting layer, wherein a first end that is one end of the first source electrode of the first pixel, a second end that is one end of the first capacitor electrode of the first pixel, and a third end that is one end of the first electrode of the second pixel face one another, the second end overlaps the first electrode of the second pixel, and the third end is between the first end and the second end.

According to some embodiments, a distance between the first end and the second end is greater than a distance between the second end and the third end.

According to some embodiments, the display device further comprising a first voltage line connected to the first drain electrode of the first pixel, wherein the first voltage line comprises a main portion and a protrusion portion protruding from the main portion, and the protrusion portion is between the first end and the second end.

According to some embodiments, the display device further comprising a shielding electrode connected to the first voltage line, wherein the shielding electrode is between the first end and the second end.

According to some embodiments, the first electrode of the second pixel overlaps the first source electrode of the first pixel.

According to some embodiments, the first electrode of the second pixel overlaps the first capacitor electrode of the first pixel.

According to some embodiments, the first capacitor electrode of the first pixel and the first capacitor electrode of the second pixel are adjacent to each other.

According to some embodiments of the present disclosure, a display device includes, a display substrate and a color conversion substrate facing each other, and a filler between the display substrate and the color conversion substrate, wherein the display substrate comprises, a first pixel and a second pixel, each comprising, a first transistor comprising a first active region, a first drain electrode and a first source electrode respectively on one side and the other side of the first active region, and a first gate electrode overlapping the first active region, a first capacitor electrode connected to the first gate electrode and overlapping the first source electrode, and a light emitting element connected to the first transistor and comprising a first electrode, a light emitting layer on the first electrode, and a second electrode on the light emitting layer, wherein a first end that is one end of the first source electrode of the first pixel, and a second end that is one end of the first source electrode of the second pixel face each other, a third end that is one end of the first capacitor electrode of the first pixel, and a fourth end that is one end of the first capacitor electrode of the second pixel face each other, and the first end is between the third end and the fourth end.

According to some embodiments, a fifth end that is one end of the first source electrode of the first pixel, a sixth end that is one end of the first capacitor electrode of the first pixel, and a seventh end that is one end of the first electrode of the second pixel face one another, the sixth end overlaps the first electrode of the second pixel, and the seventh end is between the fifth end and the sixth end.

In a display device according to some embodiments of the present disclosure, a node connected to a gate electrode of one pixel and a node connected to a gate electrode of another pixel are adjacent to each other, such that a coupling phenomenon in which the voltage is applied to the gate electrode of one pixel by the voltage applied to the gate electrode of another pixel may be relatively reduced or minimized.

In a display device according to some embodiments of the present disclosure, a node connected to a pixel electrode of one pixel overlaps a node connected to a gate electrode of another pixel, such that a coupling phenomenon in which the voltage is applied to the pixel electrode of one pixel by the voltage applied to the pixel electrode of another pixel may be relatively reduced or minimized.

In a display device according to some embodiments of the present disclosure, the edge discoloration in which a color other than white or black is displayed at a boundary between white and black may be relatively reduced or minimized at upper, lower, left, and right sides of a pixel.

However, the characteristics of embodiments according to the present disclosure are not limited to those described above and various other characteristics are incorporated herein.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a schematic perspective view showing a display device according to some embodiments;

FIG. 2 is a schematic cross-sectional view of the display device taken along the line I-I′ of FIG. 1 according to some embodiments;

FIG. 3 is a plan view illustrating a display substrate and other components according to some embodiments;

FIG. 4 is a diagram illustrating pixels and lines of a display device according to some embodiments;

FIG. 5 is a plan view schematically illustrating a display area of a display substrate according to some embodiments;

FIG. 6 is a cross-sectional view of the display device taken along the line II-II′ of FIG. 5 according to some embodiments;

FIG. 7 is a circuit diagram illustrating a pixel of a display device according to some embodiments;

FIG. 8 is a layout diagram illustrating a thin film transistor layer and a light emitting element layer of a display device according to some embodiments;

FIG. 9 is a cross-sectional view taken along the line III-III′ of FIG. 8 according to some embodiments;

FIG. 10 is a cross-sectional view taken along the line IV-IV′ of FIG. 8 according to some embodiments;

FIG. 11 is an enlarged view of the area A of FIG. 8 according to some embodiments;

FIG. 12 is a cross-sectional view taken along the line V-V′ of FIG. 11 according to some embodiments;

FIG. 13 is an enlarged view of the area B of FIG. 8 according to some embodiments;

FIG. 14 is a cross-sectional view taken along the line VI-VI′ of FIG. 13 according to some embodiments;

FIG. 15 is a layout diagram illustrating a thin film transistor layer and a light emitting element layer of a display device according to some embodiments;

FIG. 16 is an enlarged view of the area C of FIG. 15; and

FIG. 17 is a cross-sectional view taken along the line VII-VII′ of FIG. 16 according to some embodiments.

### DETAILED DESCRIPTION

The invention will now be described more fully hereinafter with reference to the accompanying drawings, in which aspects of some embodiments of the present invention are shown. This invention may, however, be embodied in different forms and should not be construed as limited to the embodiments set forth herein. Rather, these embodiments are provided so that this disclosure will be more thorough and more complete, and will more fully convey the scope of embodiments according to the present invention to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, aspects of some embodiments of the present disclosure will be described in more detail with reference to the accompanying drawings.

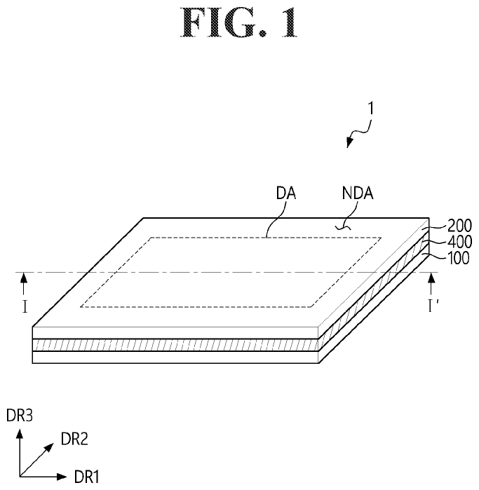

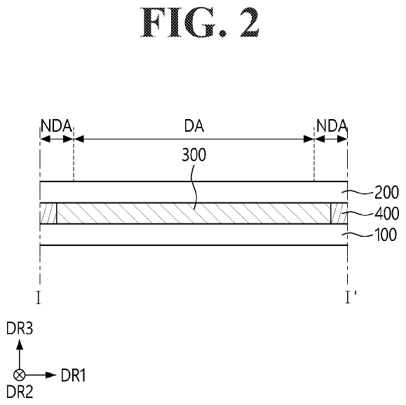

FIG. 1 is a schematic perspective view showing a display device according to some embodiments. FIG. 2 is a schematic cross-sectional view of the display device taken along the line I-I′ of FIG. 1.

Referring to FIGS. 1 and 2, a display device 1 may be applied to a variety of electronic apparatuses, i.e., small and medium electronic devices such as a tablet PC, a smartphone, a car navigation unit, a camera, a center information display (CID) provided in a vehicle, a wristwatch-type electronic device, a personal digital assistant (PDA), a portable multimedia player (PMP) and a game console, and medium and large electronic devices such as a television, an external billboard, a monitor, a personal computer and a laptop computer. These are merely suggested as examples, but the display device 1 may also be applied to other electronic devices without departing from the spirit and scope of embodiments according to the present disclosure.

According to some embodiments, the display device 1 may have a rectangular shape in a plan view. The display device 1 may include two long sides extending in a first direction DR1 and two short sides extending in a second direction DR2 intersecting the first direction DR1. A corner where the long side and the short side of the display device 1 meet may have a right angle. However, embodiments according to the present disclosure are not limited thereto, and the corner may have a curved surface. According to some embodiments, the long side may extend in the second direction DR2, and the short side may extend in the first direction DR1. The planar shape of the display device 1 is not limited to the illustrated shape, but may have a circular shape or other shapes.

In the illustrated figure, the first direction DR1 and the second direction DR2 cross each other as horizontal directions. For example, the first direction DR1 and the second direction DR2 may be orthogonal to each other. In addition, the third direction DR3 crosses the first direction DR1 and the second direction DR2, and may be, for example, perpendicular directions orthogonal to each other. Unless otherwise defined, in the present specification, directions indicated by arrows of the first to third directions DR1, DR2, and DR3 may be referred to as one side, and the opposite direction may be referred to as the other side. Also, the terms “above,” “upper side,” “upper portion,” “top,” and “top surface,” as used herein, refer to a direction indicated by an arrow in the drawing in the third direction DR3 based on the drawings, and the terms “below,” “lower side,” “lower portion,” “bottom,” and “bottom surface,” as used herein, refer to a direction opposite to the direction indicated by the arrow in the third direction DR3 based on the drawings.

The display device 1 may include a display area DA displaying images and a non-display area NDA not displaying images. According to some embodiments, the non-display area NDA may be located or arranged around (e.g., in a periphery or outside a footprint of) the display area DA and may surround the display area DA.

According to some embodiments, the display device 1 may include, as a schematic stacked structure, a display substrate 100 and a color conversion substrate 200 facing the display substrate 100, and may further include a sealing portion 400 for coupling the display substrate 100 and the color conversion substrate 200, and a filler 300 filled between the display substrate 100 and the color conversion substrate 200.

The display substrate 100 may include elements and circuits for displaying images, for example, a pixel circuit such as a switching element, a pixel defining layer and a self-light emitting element that define an emission area and a non-emission area, which will be described later, in the display area DA. According to some embodiments, the self-light emitting element may include at least one of an organic light emitting diode, a quantum dot light emitting diode, an inorganic micro light emitting diode (e.g., micro LED), or an inorganic nano light emitting diode (e.g., nano LED). Hereinafter, for simplicity of description, a case where the self-light emitting element is an organic light emitting element will be described as an example.

The color conversion substrate 200 may be located above the display substrate 100, facing the display substrate 100. According to some embodiments, the color conversion substrate 200 may include a color conversion pattern for converting the color of incident light. According to some embodiments, the color conversion pattern may include at least one of a color filter and a wavelength conversion pattern.

The sealing portion 400 may be positioned between the display substrate 100 and the color conversion substrate 200 in the non-display area NDA. The sealing portion 400 may be arranged along edges of the display substrate 100 and the color conversion substrate 200 in the non-display area NDA to surround the display area DA in a plan view. The display substrate 100 and the color conversion substrate 200 may be bonded to each other through the sealing portion 400.

According to some embodiments, the sealing portion 400 may be made of an organic material. For example, the sealing portion 400 may be made of an epoxy-based resin, but embodiments according to the present disclosure are not limited thereto.

The filler 300 may be positioned in a space surrounded by the sealing portion 400 between the display substrate 100 and the color conversion substrate 200. The filler 300 may fill the space between the display substrate 100 and the color conversion substrate 200.

According to some embodiments, the filler 300 may be made of a material that can transmit light. According to some embodiments, the filler 300 may be made of an organic material. For example, the filler 300 may be formed of a silicon-based organic material, an epoxy-based organic material, or the like, but embodiments according to the present disclosure are not limited thereto. According to some embodiments, the filler 300 may be omitted.

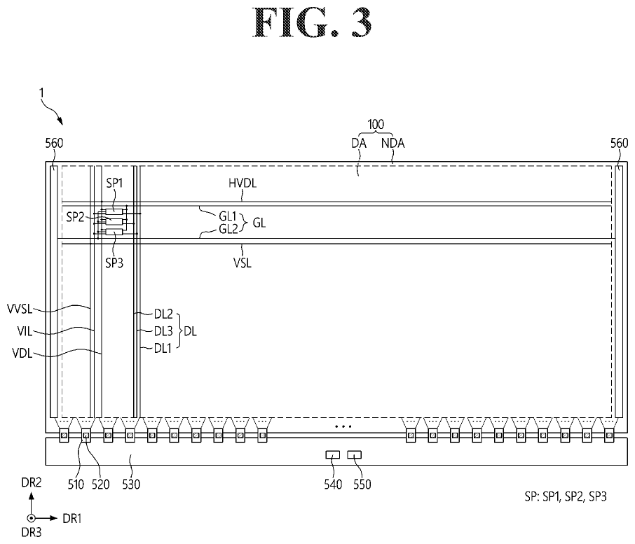

FIG. 3 is a plan view illustrating a display substrate and other components according to some embodiments.

Referring to FIG. 3, the display device 1 may include the display substrate 100, a flexible film 510, a display driver 520, a circuit board 530, a timing controller 540, a power supply unit 550, and a gate driver 560.

The display substrate 100 may have a rectangular shape in a plan view. For example, the display substrate 100 may have a rectangular shape, in a plan view (e.g., a view perpendicular or normal with respect to a display surface of the display device 1), having a long side in the first direction DR1 and a short side in the second direction DR2. A corner where the long side in the first direction DR1 and the short side in the second direction DR2 meet may be right-angled or rounded with a curvature (e.g., a set or predetermined curvature). The planar shape of the display substrate 100 is not limited to the rectangular shape, and may be formed in another polygonal shape, a circular shape or an elliptical shape, and the display substrate 100 may have rounded corners according to some embodiments. For example, the display substrate 100 may be formed to be flat, but embodiments according to the present disclosure are not limited thereto. In another example, the display substrate 100 may be bent with a curvature (e.g., a set or predetermined curvature).

The display substrate 100 may include a display area DA and a non-display area NDA.

The display area DA, which is an area for displaying an image, may be defined as the central area of the display substrate 100. The display area DA may include a pixel SP, a gate line GL, a data line DL, an initialization voltage line VIL, a first voltage line VDL, a horizontal voltage line HVDL, and a vertical voltage line VVSL, and a second voltage line VSL. The pixel SP may be formed in each pixel area at intersections of the data lines DL and the gate lines GL. The pixels SP may include first to third pixels SP1, SP2, and SP3. Each of the first to third pixels SP1, SP2, and SP3 may be connected to the gate line GL and the data line DL. Each of the first to third pixels SP1, SP2, and SP3 may be defined as a minimum unit area that outputs light.

Each of the first to third pixels SP1, SP2, and SP3 may include an organic light emitting diode (OLED) having an organic light emitting layer, a quantum dot light emitting diode (LED) including a quantum dot light emitting layer, a micro LED, or an inorganic LED having an inorganic semiconductor.

The first pixel SP1 may emit light of a first color such as red light, the second pixel SP2 may emit light of a second color such as green light, and the third pixel SP3 may emit light of a third color such as blue light. The pixel circuits of the second pixel SP2, the first pixel SP1, and the third pixel SP3 may be arranged in the opposite direction of the second direction DR2, but the arrangement direction of the pixel circuits is not limited thereto.

The gate line GL may include a first gate line GL1 and a second gate line GL2. The first gate lines GL1 may extend in the first direction DR1 and may be spaced apart from each other in the second direction DR2. The first gate line GL1 may receive a first gate signal from the gate driver 560 and supply the first gate signal to the first to third pixels SP1, SP2, and SP3.

The second gate lines GL2 may extend in the first direction DR1 and may be spaced apart from each other in the second direction DR2. The second gate line GL2 may receive a second gate signal from the gate driver 560 and supply the second gate signal to the first to third pixels SP1, SP2, and SP3.

The data lines DL may extend in the second direction DR2 and may be spaced apart from each other in the first direction DR1. The data lines DL may include first to third data lines DL1, DL2, and DL3. Each of the first to third data lines DL1, DL2, and DL3 may supply a data voltage to each of the first to third pixels SP1, SP2, and SP3.

The initialization voltage lines VIL may extend in the second direction DR2 and may be spaced apart from each other in the first direction DR1. The initialization voltage line VIL may supply the initialization voltage received from the display driver 520 to the pixel circuit of each of the first to third pixels SP1, SP2 and SP3. The initialization voltage line VIL may receive a sensing signal from the pixel circuit of each of the first to third pixels SP1, SP2 and SP3 to supply the sensing signal the display driver 520.

The first voltage lines VDL may extend in the second direction DR2 and may be spaced apart from each other in the first direction DR1. The first voltage line VDL may supply a driving voltage or a high potential voltage received from the power supply unit 550 to the first to third pixels SP1, SP2, and SP3.

The horizontal voltage lines HVDL may extend in the first direction DR1 and may be spaced apart from each other in the second direction DR2. The horizontal voltage line HVDL may be connected to the first voltage line VDL. The horizontal voltage line HVDL may receive a driving voltage or a high potential voltage from the first voltage line VDL.

The vertical voltage lines VVSL may extend in the second direction DR2 and may be spaced apart from each other in the first direction DR1. The vertical voltage line VVSL may be connected to the second voltage line VSL. The vertical voltage line VVSL may supply the low potential voltage received from the power supply unit 550 to the second voltage line VSL.

The second voltage lines VSL may extend in the first direction DR1 and may be spaced apart from each other in the second direction DR2. The second voltage line VSL may supply a low potential voltage to the first to third pixels SP1, SP2, and SP3.

The connection relationship of the pixel SP, the gate line GL, the data line DL, the initialization voltage line VIL, the first voltage line VDL, the horizontal voltage line HVDL, the vertical voltage line VVSL, and the second voltage line VSL may be designed and changed according to the number and arrangement of the pixels SP.

The non-display area NDA may be defined as the remaining area of the display substrate 100 except the display area DA. For example, the non-display area NDA may include fan-out lines connecting the data line DL, the initialization voltage line VIL, the first voltage line VDL, and the vertical voltage line VVSL to the display driver 520, the gate driver 560, and a pad portion connected to the flexible film 510.

The flexible film 510 may be connected to the pad portion located below the non-display area NDA. Input terminals provided on one side of the flexible film 510 may be attached to the circuit board 530 by a film attaching process, and output terminals provided at the other side of the flexible film 510 may be attached to the pad portion by the film attaching process. For example, the flexible film 510 may be bent like a tape carrier package or a chip on film. The flexible film 510 may be bent toward the lower portion of the display substrate 100 to reduce the bezel area of the display device 1.

The display driver 520 may be mounted on the flexible film 510. For example, the display driver 520 may be implemented as an integrated circuit (IC). The display driver 520 may receive digital video data and a data control signal from the timing controller 540, and according to the data control signal, convert the digital video data to an analog data voltage to supply it to the data lines DL through the fan-out lines.

A circuit board 530 may support a timing controller 540 and the power supply unit 550, and supply signals and power to the display driver 520. For example, the circuit board 530 may supply a signal supplied from the timing controller 540 and a power voltage supplied from the power supply unit 550 to the flexible film 510 and the display driver 520 to display an image on each pixel. To this end, a signal line and a power line may be provided on the circuit board 530.

The timing controller 540 may be mounted on the circuit board 530 and receive image data and a timing synchronization signal supplied from the display driving system or a graphic device through a user connector provided on the circuit board 530. The timing controller 540 may generate digital video data by arranging the image data to fit the pixel arrangement structure based on the timing synchronization signal, and may supply the generated digital video data to the display driver 520. The timing controller 540 may generate the data control signal and the gate control signal based on the timing synchronization signal. The timing controller 540 may control the data voltage supply timing of the display driver 520 based on the data control signal, and may control the gate signal supply timing of the gate driver 560 based on the gate control signal.

The power supply unit 550 may be located on the circuit board 530 to supply a power voltage to the flexible film 510 and the display driver 520. For example, the power supply unit 550 may generate a driving voltage or a high potential voltage and supply it to the first voltage line VDL, may generate a low potential voltage and supply it to the vertical voltage line VVSL, and may generate an initialization voltage and supply it to the initialization voltage line VIL.

The gate driver 560 may be located on the left and right sides of the non-display area NDA. The gate driver 560 may generate a gate signal based on the gate control signal supplied from the timing controller 540. The gate control signal may include a start signal, a clock signal, and a power voltage, but the present disclosure is not limited thereto. The gate driver 560 may supply a gate signal to the gate line GL according to a set order.

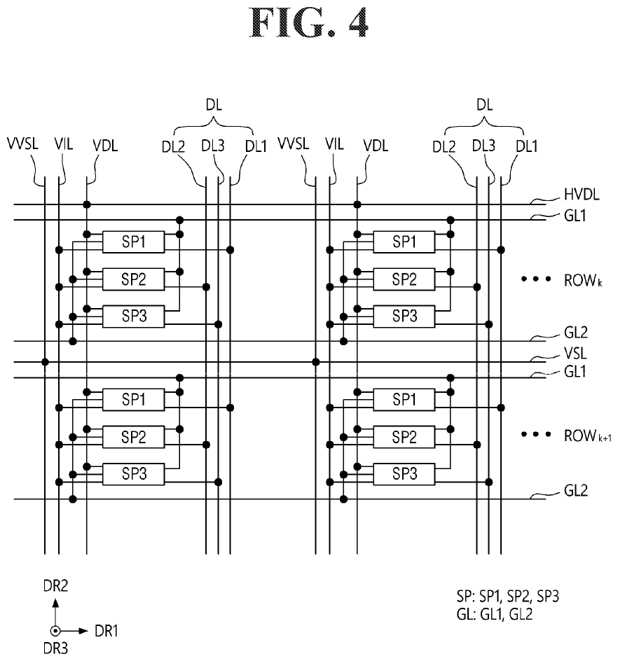

FIG. 4 is a diagram illustrating pixels and lines of a display device according to some embodiments.

Referring to FIG. 4 in addition to FIG. 3, the pixels SP may include first to third pixels SP1, SP2, and SP3. The pixel circuits of the first pixel SP1, the second pixel SP2, and the third pixel SP3 may be arranged in the opposite direction of the second direction DR2, but the arrangement direction of the pixel circuits is not limited thereto.

Each of the first to third pixels SP1, SP2, and SP3 may be connected to the first voltage line VDL, the initialization voltage line VIL, the gate line GL, and the data line DL.

The first voltage line VDL may extend in the second direction DR2. The first voltage line VDL may be located on the left side of the pixel circuits of the first to third pixels SP1, SP2 and SP3. The first voltage line VDL may supply a driving voltage or high potential voltage to a transistor of each of the first to third pixels SP1, SP2 and SP3.

The horizontal voltage line HVDL may extend in the first direction DR1. The horizontal voltage line HVDL may be located above the first gate line GL1 located in a k^{th} row ROWₖ (k being a positive integer). The horizontal voltage line HVDL may be connected to the first voltage line VDL. The horizontal voltage line HVDL may receive a driving voltage or a high potential voltage from the first voltage line VDL.

The initialization voltage line VIL may extend in the second direction DR2. The initialization voltage line VIL may be located on the left side of the auxiliary line of the second gate line GL2, which is branched in the second direction DR2. The initialization voltage line VIL may be located between the auxiliary line of the second gate line GL2, which is branched in the second direction DR2, and the vertical voltage line VVSL. The initialization voltage line VIL may supply an initialization voltage to the pixel circuit of each of the first to third pixels SP1, SP2, and SP3. The initialization voltage line VIL may receive a sensing signal from the pixel circuit of each of the first to third pixels SP1, SP2 and SP3 to supply the sensing signal the display driver 520.

The vertical voltage line VVSL may extend in the second direction DR2. The vertical voltage line VVSL may be located on the left side of the initialization voltage line VIL. The vertical voltage line VVSL may be connected between the power supply unit 550 and the second voltage line VSL. The vertical voltage line VVSL may supply the low potential voltage supplied from the power supply unit 550 to the second voltage line VSL.

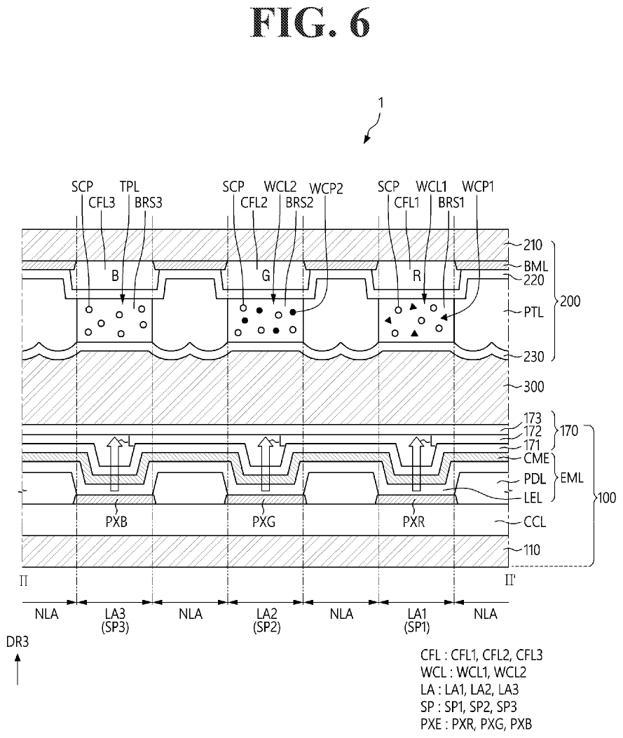

The second voltage line VSL may extend in the first direction DR1. The second voltage line VSL may be located above the first gate line GL1 located in a (k+1)^{th} row ROWₖ₊₁. The second voltage line VSL may supply the low potential voltage received from the vertical voltage line VVSL to a light emitting element layer EML (see FIG. 6) of the first to third pixels SP1, SP2, and SP3.

The first gate line GL1 may extend in the first direction DR1. The first gate line GL1 may be located above the pixel circuit of the first pixel SP1. At least a part of the first gate line GL1 may extend in a direction opposite to the second direction DR2. For example, the first gate line GL1 may include an auxiliary line branched from the right sides of the first to third pixels SP1, SP2, and SP3 and extending in the direction opposite to the second direction DR2. The auxiliary line of the first gate line GL1 may be located on the right sides of the pixel circuits of the first to third pixels SP1, SP2, and SP3. The first gate line GL1 may supply the first gate signal received from the gate driver 560 to the pixel circuits of the first to third pixels SP1, SP2, and SP3 through the auxiliary line extending in the direction opposite to the second direction DR2.

The second gate line GL2 may extend in the first direction DR1. The second gate line GL2 may be located under the pixel circuit of the third pixel SP3. At least a part of the second gate line GL2 may extend in the second direction DR2. For example, the second gate line GL2 may include an auxiliary line branched from the left side of the first voltage line VDL and extending in the second direction DR2. The auxiliary line of the second gate line GL2 may be located on the left of the first voltage line VDL. The second gate line GL2 may supply the second gate signal received from the gate driver 560 to the pixel circuits of the first to third pixels SP1, SP2, and SP3 through the auxiliary line extending in the second direction DR2.

The data lines DL may extend in the second direction DR2. The data lines DL may supply a data voltage to the pixel SP. The data lines DL may include first to third data lines DL1, DL2, and DL3.

The second data line DL2 may extend in the second direction DR2. The second data line DL2 may be located on the right side of the auxiliary line of the first gate line GL1. The second data line DL2 may supply the data voltage received from the display driver 520 to the pixel circuit of the second pixel SP2.

The third data line DL3 may extend in the second direction DR2. The third data line DL3 may be located on the right side of the second data line DL2. The third data line DL3 may supply the data voltage received from the display driver 520 to the pixel circuit of the third pixel SP3.

The first data line DL1 may extend in the second direction DR2. The first data line DL1 may be located on the right side of the third data line DL3. The first data line DL1 may supply the data voltage received from the display driver 520 to the pixel circuit of the first pixel SP1.

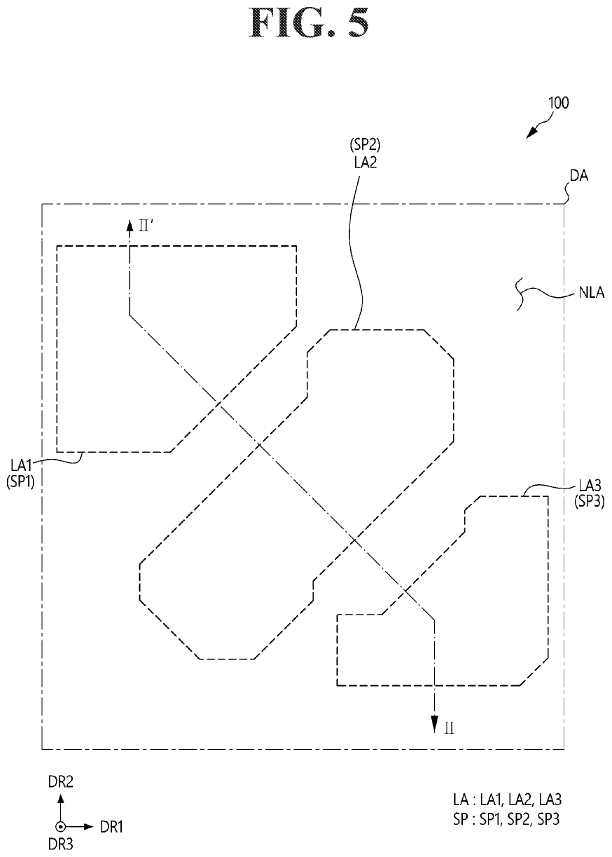

FIG. 5 is a plan view schematically illustrating a display area of a display substrate according to some embodiments.

Referring to FIG. 5 in addition to FIGS. 1 and 2, a plurality of emission areas LA and a non-emission area NLA may be defined in the display area DA of the display substrate 100. The plurality of emission areas LA may be regions where light generated by the light emitting element of the display substrate 100 is emitted to the outside of the display substrate 100, and the non-emission area NLA may be a region where light is not emitted to the outside of the display substrate 100.

The plurality of emission area LA may include a first emission area LA1, a second emission area LA2, and a third emission area LA3.

The light emitted from the display substrate 100 to the color conversion substrate 200 in the plurality of emission areas LA may be light of a third color. According to some embodiments, the light of the third color may be blue light, and may have a peak wavelength within a range of about 440 nm to about 480 nm. The peak wavelength may refer to a wavelength at which the intensity of light is maximized within a wavelength range. However, embodiments according to the present disclosure are not limited thereto, and the light emitted from the display substrate 100 to the color conversion substrate 200 in the plurality of emission areas LA may be light in an ultraviolet region.

The first emission area LA1, the second emission area LA2, and the third emission area LA3 may constitute the first pixel SP1, the second pixel SP2, and the third pixel SP3, respectively. The first emission area LA1, the second emission area LA2, and the third emission area LA3 may be repeatedly arranged along the first direction DR1 and the second direction DR2 in the entire display area DA. The first emission area LA1, the second emission area LA2, and the third emission area LA3 may constitute one unit color pixel.

The first to third emission areas LA1, LA2, and LA3 may be arranged in a diagonal direction defined by the opposite directions of the first direction DR1 and the second direction DR2. For example, in one unit color pixel, the first emission area LA1 may be located substantially at an upper left portion in a plan view, the second emission area LA2 may be located substantially at the center in a plan view, and a third emission area LA3 may be located substantially at a lower right portion in a plan view.

However, the arrangement order of the first to third emission areas LA1, LA2, and LA3 is not limited thereto. Further, according to some embodiments, the first to third emission areas LA1, LA2, and LA3 may be arranged in a diagonal direction defined by the first direction DR1 and the second direction DR2.

According to some embodiments, the first emission area LA1 may be a polygon having a constant width in the first direction DR1 and the second direction DR2. In the drawing, the first emission area LA1 is illustrated as a pentagon, for example. The second emission area LA2 may be a polygon having a constant width extending in the diagonal direction defined by the first direction DR1 and the second direction DR2. In the drawing, the second emission area LA2 is illustrated as a polygon having stepped portions at both ends, for example. The third emission area LA3 may be a polygon having a constant width in the first direction DR1 and the second direction DR2. In the drawing, the third emission area LA3 is illustrated as a polygon including portions protruding in the opposite direction of the first direction DR1 and in the second direction DR2.

As illustrated in the drawing, the widths and shapes of the first to third emission areas LA1, LA2, and LA3 may be different from each other. For example, the first emission area LA1 may have similar widths in the first direction DR1 and the second direction DR2. The second emission area LA2 may have a large width in the diagonal direction defined by the first direction DR1 and the second direction DR2, and may have a small width in the diagonal direction defined by the opposite directions of the first direction DR1 and the second direction DR2. Accordingly, the second emission area LA2 may have a substantially polygonal shape elongated in the diagonal direction defined by the first direction DR1 and the second direction DR2. The third emission area LA3 may have similar widths in the first direction DR1 and the second direction DR2. However, embodiments according to the present disclosure are not limited thereto, and in some embodiments, the first to third emission areas LA1, LA2, and LA3 may have the same shape.

In the display device 1 according to some embodiments, the first to third emission areas LA1, LA2, and LA3 are arranged in the diagonal direction, so that the variation in the distribution of the upper, lower, left, and right emission areas LA in one unit color pixel may be reduced. Accordingly, an edge discoloration in which a color other than white or black is displayed at the boundary between white and black may be minimized at the upper, lower, left, and right sides of the pixel (for example, the edges of the pixel).

Further, the second emission area LA2 has a shape extending in the diagonal direction defined by the first direction DR1 and the second direction DR2, and the extension length thereof is increased, so that the variation in the distribution of the upper, lower, left, and right emission areas LA in one unit color pixel may be further reduced, thereby minimizing the edge discoloration at the upper, lower, left and right sides of the pixel (for example, the edges of the pixel).

The non-emission area NLA may be positioned around the emission area LA of the display substrate 100 in the display area DA. The non-emission area NLA may be positioned not only around the emission area LA, but also between the first emission area LA1 and the second emission area LA2, between the second emission area LA2 and the third emission area LA3, and between the third emission area LA3 and the first emission area LA1.

In some embodiments, the boundary between the emission area LA and the non-emission area NLA may be defined by an opening of a pixel defining layer PDL (see FIG. 6) to be described later and an outer wall surrounding the opening.

The light emitted from the emission area LA of the display substrate 100 may be provided to the outside of the display device 1 while passing through the light transmitting area of the color conversion substrate 200.

FIG. 6 is a cross-sectional view of the display device taken along the line II-II′ of FIG. 5.

Referring to FIG. 6 in addition to FIG. 5, the display device 1 may include the display substrate 100, the color conversion substrate 200 facing the display substrate 100, and the filler 300 for bonding them.

The display substrate 100 may include a first substrate 110, a circuit layer CCL, a light emitting element layer EML, and an encapsulation structure 170.

The first substrate 110 may include a transparent material. For example, the first substrate 110 may include a transparent insulating material such as glass, quartz, or the like. The first substrate 110 may be a rigid substrate. However, the first substrate 110 is not limited thereto. The first substrate 110 may include plastic such as polyimide or the like, and may have a flexible property such that it can be twisted, bent, folded, or rolled.

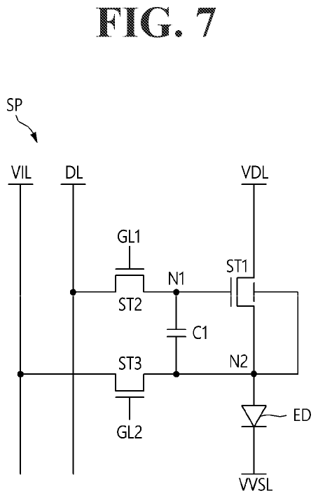

The circuit layer CCL (for example, a thin film transistor layer) may be located on the first substrate 110. A description of the circuit layer CCL will be described later with reference to FIG. 7 and the like.

The light emitting element layer EML may be located on the circuit layer CCL. The light emitting element layer EML may include a pixel electrode PXE, a pixel defining layer PDL, a light emitting layer LEL, and a common electrode CME.

The pixel electrode PXE may be a first electrode (e.g., an anode electrode) of a light emitting diode. The pixel electrode PXE may have a stacked structure formed by stacking a material layer having a high work function, such as indium tin oxide (ITO), indium zinc oxide (IZO), zinc oxide (ZnO) and indium oxide (In₂O₃), and a reflective material layer such as silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or a mixture thereof. The material layer having a high work function may be located above the reflective material layer and located closer to a light emitting layer LEL. The pixel electrode PXE may have a multilayer structure such as ITO/Mg, ITO/MgF, ITO/Ag and ITO/Ag/ITO, but embodiments according to the present disclosure are not limited thereto.

The pixel electrode PXE may include a first pixel electrode PXR, a second pixel electrode PXG, and a third pixel electrode PXB. The first pixel electrode PXR may be arranged to overlap the first emission area LA1. The first pixel electrode PXR may be arranged to overlap the first emission area LA1. The third pixel electrode PXB may be arranged to overlap the third emission area LA3.

The pixel defining layer PDL may be arranged along the boundary of the pixel SP on one surface of the first substrate 110. The pixel defining layer PDL may be located on the pixel electrode PXE and may include an opening to expose the pixel electrode PXE. The emission area LA and the non-emission area NLA may be distinguished by the pixel defining layer PDL and the openings of the pixel defining layer PDL.

The pixel defining layer PDL may include an organic insulating material such as acrylic resin, epoxy resin, phenolic resin, polyamide resin, polyimide resin, unsaturated polyester resin, polyphenylene resin, polyphenylenesulfide resin or benzocyclobutene (BCB). The pixel defining layer PDL may include an inorganic material.

The light emitting layer LEL may be located on the pixel electrode PXE exposed by the pixel defining layer PDL. The light emitting layer LEL may be in contact with not only the pixel electrode PXE, but also the side surface and the top surface of the pixel defining layer PDL. The light emitting layer LEL may be connected across the emission area LA and the pixel SP. The light emitting layer LEL may be arranged across the emission area LA and the pixel SP. Accordingly, the wavelength of light L emitted from the light emitting layer LEL may be the same for each of the emission areas LA1, LA2, and LA3. For example, the light emitting layer LEL of each of the emission areas LA1, LA2, and LA3 may emit blue light or ultraviolet rays, and a color control structure which will be described later may include a wavelength conversion layer WCL, thereby displaying a color for each pixel SP.

According to some embodiments, the light emitting layers LEL may be spaced apart from each other for each of the emission areas LA1, LA2, and LA3 distinguished by the pixel defining layer PDL. In this case, the wavelength of light L emitted from each light emitting layer LEL may be the same for each of the emission areas LA1, LA2, and LA3.

According to some embodiments in which the display device 1 is an organic light emitting display, the light emitting layer LEL may include an organic layer containing an organic material. The organic layer may have an organic light emitting layer, and in some cases, may further have at least one of a hole injection layer, a hole transport layer, an electron transport layer, or an electron injection layer as an auxiliary layer for light emission. According to some embodiments, when the display device 1 is a micro LED display, a nano LED display or the like, the light emitting layer LEL may include an inorganic material such as an inorganic semiconductor.

In some embodiments, the light emitting layer LEL may have a tandem structure in which a plurality of organic light emitting layers are superposed in the thickness direction and a charge generation layer is located between the organic light emitting layers. The respective organic light emitting layers superposed may emit light of the same wavelength, or may emit light of different wavelengths. At least some of the light emitting layers LEL of each pixel SP may be separated from or connected to the same layer of a neighboring pixel SP by the pixel defining layer PDL.

The common electrode CME may be arranged on the light emitting layer LEL. The common electrode CME may be connected across the emission area LA and the pixel SP. The common electrode CME may be a full surface electrode arranged across the emission area LA and the pixel SP. The common electrode CME may be a second electrode (e.g., a cathode electrode) of a light emitting diode. The common electrode CME may include a material layer having a low work function, such as Li, Ca, LiF/Ca, LiF/Al, Al, Mg, Ag, Pt, Pd, Ni, Au Nd, Ir, Cr, BaF, Ba or a compound or mixture thereof (e.g., a mixture of Ag and Mg). The common electrode CME may further include a transparent metal oxide layer located on the material layer having a low work function.

The pixel electrode PXE, the light emitting layer LEL, and the common electrode CME may constitute a light emitting element (e.g., an OLED). Light emitted from the light emitting layer LEL may be emitted upward through the common electrode CME.

The encapsulation structure 170 may be located on the common electrode CME. The encapsulation structure 170 may include at least a thin film encapsulation layer. For example, the encapsulation structure 170 may include a first inorganic film 171, an organic film 172, and a second inorganic film 173.

The first inorganic film 171 may be located on the light emitting element layer EML. The first inorganic film 171 may include silicon nitride (SiNx), silicon oxide (SiOx), silicon oxynitride (SiOxNy), or the like.

The organic film 172 may be located on the first inorganic film 171. The organic film 172 may include an organic insulating material selected from the group consisting of acrylic resin, epoxy resin, phenolic resin, polyamide resin, polyimide resin, unsaturated polyester resin, polyphenylene resin, polyphenylenesulfide resin and benzocyclobutene (BCB).

The second inorganic film 173 may be located on the organic film 172. The second inorganic film 173 may include the same material as the first inorganic film 171 described above. For example, the second inorganic film 173 may include silicon nitride (SiNx), silicon oxide (SiOx), silicon oxynitride (SiOxNy), or the like.

In some embodiments, some layers of the encapsulation structure 170 or the entire encapsulation structure 170 may be omitted. When the encapsulation structure 170 is omitted, the filler 300, the sealing portion 400, and the color conversion substrate 200 may be directly located on the light emitting element layer EML, and the filler 300, the sealing portion 400, and the color conversion substrate 200 may directly perform an encapsulation function.

The color conversion substrate 200 may be arranged to face the display substrate 100 on the encapsulation structure 170. The color conversion substrate 200 may include a second substrate 210, a light blocking member BML, a color filter layer CFL, a first capping layer 220, a partition wall PTL, a wavelength conversion layer WCL, a light transmitting layer TPL, and a second capping layer 230.

The second substrate 210 may include a transparent material. The second substrate 210 may include a transparent insulating material such as glass, quartz, or the like. The second substrate 210 may be a rigid substrate. However, the second substrate 210 is not limited thereto. The second substrate 210 may include plastic such as polyimide or the like, and may have a flexible property such that it can be twisted, bent, folded, or rolled.

The second substrate 210 may be the same substrate as the first substrate 110, but may have a different material, thickness, transmittance and the like. For example, the second substrate 210 may have a higher transmittance than the first substrate 110. The second substrate 210 may be thicker or thinner than the first substrate 110.

The light blocking member BML may be arranged along the boundary of the pixel SP on one surface of the second substrate 210 that faces the first substrate 110. The light blocking member BML may overlap the pixel defining layer PDL of the display substrate 100 and may be positioned in the non-emission areas NLA. The light blocking member BML may include openings to expose the surface of the second substrate 210 overlapping the emission areas LA. The light blocking member BML may be formed in a grid shape in a plan view.

The light blocking member BML may include an organic material. The light blocking member BML may reduce color distortion due to external light reflection by absorbing the external light. Further, the light blocking member BML may serve to prevent light which is emitted from the light emitting layer LEL from entering the adjacent pixels SP.

According to some embodiments, the light blocking member BML may absorb all visible wavelengths. The light blocking member BML may include a light absorbing material. For example, the light blocking member BML may be formed of a material used as a black matrix of the display device 1.

According to some embodiments, the light blocking member BML may absorb light of specific wavelengths among visible wavelengths and transmit light of other wavelengths. For example, the light blocking member BML may include the same material as the color filter layer CFL. For example, the light blocking member BML may be made of the same material as a blue color filter layer. In some embodiments, the light blocking member BML may be integrally formed with the blue color filter layer. Alternatively, the light blocking member BML may be omitted.

The color filter layer CFL may be located on one surface of the second substrate 210 on which the light blocking member BML is located. The color filter layers CFL may be provided on the surface of the second substrate 210 which is exposed through the openings of the light blocking member BML. Further, each color filter layer CFL may be partially located on the adjacent light blocking member BML.

The color filter layer CFL may include a first color filter layer CFL1 located in the first pixel SP1, a second color filter layer CFL2 located in the second pixel SP2, and a third color filter layer CFL3 located in the third pixel SP3. Each of the color filter layers CFL may include a colorant such as a dye or a pigment that absorbs wavelengths other than the corresponding color wavelength. The first color filter layer CFL1 may be a red color filter layer, the second color filter layer CFL2 may be a green color filter layer, and the third color filter layer CFL3 may be a blue color filter layer. In the drawing, neighboring color filter layers CFL are arranged to be spaced apart from each other on the light blocking member BML, but the neighboring color filter layers CFL may partially overlap each other on the light blocking member BML.

The first capping layer 220 may be located on the color filter layer CFL. The first capping layer 220 may prevent impurities such as moisture or air from permeating from the outside and damaging or contaminating the color filter layers CFL. Further, the first capping layer 220 may prevent the colorants of the color filter layers CFL from being diffused into other members.

The first capping layer 220 may be in direct contact with one surface (bottom surface in FIG. 6) of the color filter layer CFL. The first capping layer 220 may be made of an inorganic material. For example, the first capping layer 220 may include silicon nitride, aluminum nitride, zirconium nitride, titanium nitride, hafnium nitride, tantalum nitride, silicon oxide, aluminum oxide, titanium oxide, tin oxide, silicon oxynitride, or the like.

The partition wall PTL may be located on the first capping layer 220. The partition wall PTL may be positioned in the non-emission area NLA. The partition wall PTL may be arranged to overlap the light blocking member BML. The partition wall PTL may include openings exposing the color filter layers CFL. The partition wall PTL may include a photosensitive organic material, but the present disclosure is not limited thereto. The partition wall PTL may further include a light blocking material.

The wavelength conversion layer WCL and/or the light transmitting layer TPL may be located in the space exposed by the opening of the partition wall PTL. The wavelength conversion layer WCL and the light transmitting layer TPL may be formed by an inkjet process using the partition wall PTL as a bank, but the present disclosure is not limited thereto.

According to some embodiments in which the light emitting layer LEL of each pixel SP emits light in a third color, the wavelength conversion layer WCL may include a first wavelength conversion pattern WCL1 located in the first pixel SP1 and a second wavelength conversion pattern WCL2 located in the second pixel SP2. The light transmitting layer TPL may be located in the third pixel SP3.

The first wavelength conversion pattern WCL1 may include a first base resin BRS1 and a first wavelength conversion material WCP1 provided in the first base resin BRS1. The second wavelength conversion pattern WCL2 may include a second base resin BRS2 and a second wavelength conversion material WCP2 provided in the second base resin BRS2. The light transmitting layer TPL may include a third base resin BRS3 and scatterers SCP provided in the third base resin BRS3.

The first to third base resins BRS1, BRS2, and BRS3 may include a light transmitting organic material. For example, the first to third base resins BRS1, BRS2, and BRS3 may include an epoxy resin, an acrylic resin, a cardo resin, an imide resin, or the like. The first to third base resins BRS1, BRS2, and BRS3 may be formed of the same material, but embodiments according to the present disclosure are not limited thereto.

The scatterer SCP may be a metal oxide particle or an organic particle. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), and the like. Examples of a material of the organic particles may include acrylic resin and urethane resin, and the like.

The first wavelength conversion material WCP1 may convert the third color into the first color, and the second wavelength conversion material WCP2 may convert the third color into the second color. The first wavelength conversion material WCP1 and the second wavelength conversion material WCP2 may be quantum dots, quantum bars, phosphors or the like. Examples of the quantum dot may include group IV nanocrystal, group II-VI compound nanocrystal, group Ill-V compound nanocrystal, group IV-VI nanocrystal, and a combination thereof. The first wavelength conversion pattern WCL1 and the second wavelength conversion pattern WCL2 may further include scatterers SCP for increasing wavelength conversion efficiency.

The light transmitting layer TPL located in the third pixel SP3 may transmit light of a third color emitted from the light emitting layer LEL while maintaining the wavelength thereof. The scatterer SCP of the light transmitting layer TPL may serve to control an emission path of the light emitted through the light transmitting layer TPL. The light transmitting layer TPL may not include a wavelength conversion material.

The second capping layer 230 may be located on the wavelength conversion layer WCL, the light transmitting layer TPL, and the partition wall PTL. The second capping layer 230 may be formed of an inorganic material. The second capping layer 230 may include a material selected from the above-mentioned materials of the first capping layer 220. The first capping layer 220 and the second capping layer 230 may be formed of the same material, but the present disclosure is not limited thereto.

The filler 300 may be located between the display substrate 100 and the color conversion substrate 200. The filler 300 may fill a space between the display substrate 100 and the color conversion substrate 200, and may serve to bond them to each other. The filler 300 may be located between the encapsulation structure 170 of the display substrate 100 and the second capping layer 230 of the color conversion substrate 200. The filler 300 may be formed of a Si-based organic material, an epoxy-based organic material, or the like, but is not limited thereto.

FIG. 7 is a circuit diagram illustrating a pixel of a display device according to some embodiments.

Referring to FIG. 7, each pixel SP may be connected to the first voltage line VDL, the data line DL, the initialization voltage line VIL, the first gate line GL1, the second gate line GL2, and the vertical voltage line VVSL.

Each of the first to third pixels SP1, SP2, and SP3 may include a pixel circuit and the light emitting element ED. The pixel circuit of each of the first to third pixels SP1, SP2, and SP3 may include first to third transistors ST1, ST2, and ST3 and a first capacitor C1.

The first transistor ST1 may include an upper gate electrode, a lower gate electrode, a drain electrode, and a source electrode. The upper gate electrode of the first transistor ST1 may be connected to a first node N1, the lower gate electrode thereof may be connected to a second node N2, the drain electrode thereof may be connected to the first voltage line VDL, and the source electrode thereof may be connected to the second node N2. The first transistor ST1 may control a drain-source current (or a driving current) based on the data voltage applied to the upper gate electrode and the lower gate electrode. The first transistor ST1 may be a driving transistor for driving the light emitting element ED.

The light emitting element ED may emit light by receiving a driving current. The light emission amount or the luminance of the light emitting element ED may be proportional to the magnitude of the driving current. The light emitting element ED may be an organic light emitting diode (OLED) having an organic light emitting layer, a quantum dot light emitting diode (LED) including a quantum dot light emitting layer, a micro LED, or an inorganic LED having an inorganic semiconductor.

The first electrode of the light emitting element ED may be connected to the second node N2, and the second electrode of the light emitting element ED may be connected to the vertical voltage line VVSL. The first electrode of the light emitting element ED may be connected to the source electrode of the first transistor ST1, the drain electrode of the third transistor ST3, and the second capacitor electrode of the first capacitor C1, through the second node N2.

The second transistor ST2 may be turned on by the first gate signal of the first gate line GWL to electrically connect the data line DL to the first node N1 which is the upper gate electrode of the first transistor ST1. The second transistor ST2 may be turned on according to the first gate signal to supply the data voltage to the first node N1. The gate electrode of the second transistor ST2 may be connected to the first gate line GL1, the drain electrode thereof may be connected to the data line DL, and the source electrode thereof may be connected to the first node N1. The source electrode of the second transistor ST2 may be connected to the upper gate electrode of the first transistor ST1 and a first capacitor electrode of the first capacitor C1 through the first node N1. The second transistor ST2 may be a switching transistor for controlling the current flowing through the first transistor ST1 and the light emitting element ED.

The third transistor ST3 may be turned on by the second gate signal of the second gate line GL2 to electrically connect the initialization voltage line VIL to the second node N2 which is the source electrode of the first transistor ST1. The third transistor ST3 may be turned on according to the second gate signal to supply the initialization voltage to the second node N2. The third transistor ST3 may be turned on according to the second gate signal to supply the sensing signal to the initialization voltage line VIL. The gate electrode of the third transistor ST3 may be connected to the second gate line GL2, the drain electrode thereof may be connected to the second node N2, and the source electrode thereof may be connected to the initialization voltage line VIL. The drain electrode of the third transistor ST3 may be connected to the source electrode of the first transistor ST1, the second capacitor electrode of the first capacitor C1, and the first electrode of the light emitting element ED, through the second node N2. The third transistor ST3 may be a switching transistor for controlling the current flowing through the first transistor ST1 and the light emitting element ED.

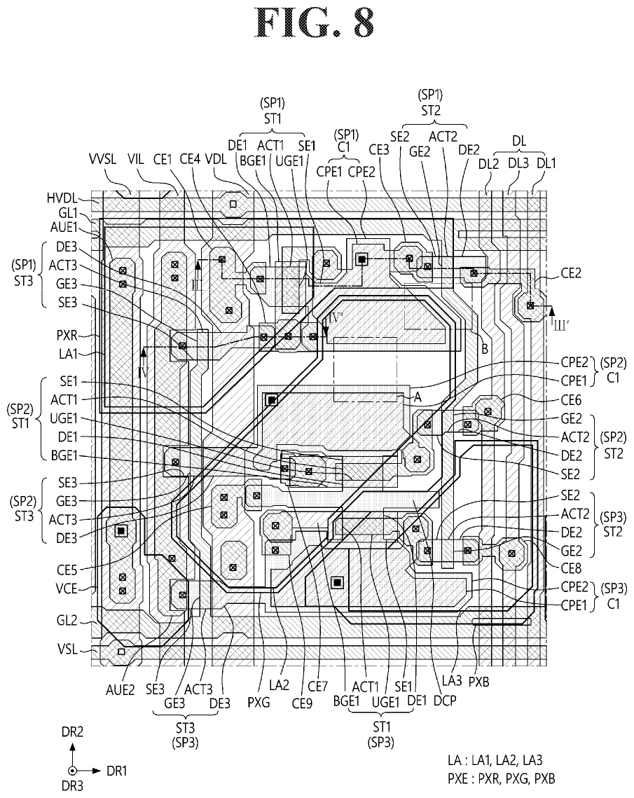

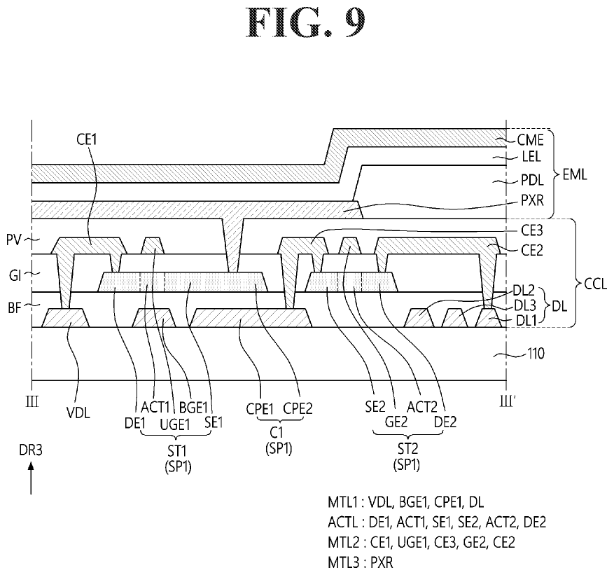

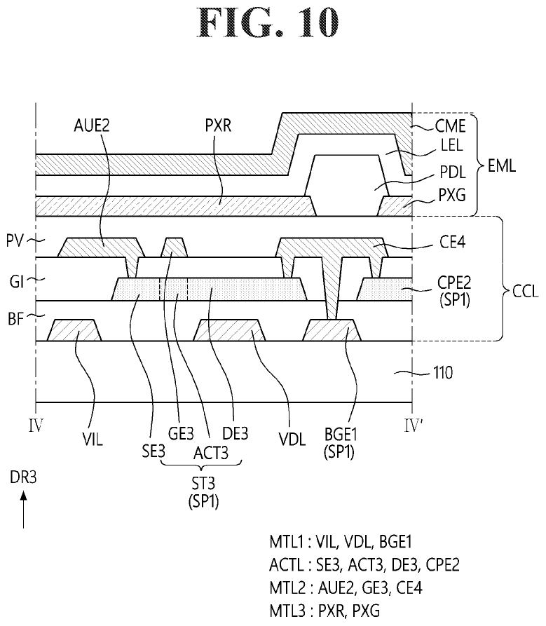

FIG. 8 is a layout diagram illustrating a thin film transistor layer and a light emitting element layer of a display device according to some embodiments. FIG. 9 is a cross-sectional view taken along the line III-III′ of FIG. 8. FIG. 10 is a cross-sectional view taken along the line IV-IV′ of FIG. 8.

Referring to FIGS. 8 to 10 in addition to FIG. 7, the circuit layer CCL may be located on the first substrate 110. The circuit layer CCL (for example, a thin film transistor layer) may include the first to third pixels SP1, SP2, and SP3, the first voltage line VDL, the horizontal voltage line HVDL, the initialization voltage line VIL, the first and second gate lines GL1 and GL2, the data line DL, the second voltage line VSL, and the vertical voltage line VVSL.

The circuit layer CCL may include a first metal layer MTL1 located on the first substrate 110, a buffer layer BF covering the first metal layer MTL1, an active layer ACTL located on the buffer layer BF, a gate insulating layer GI covering the active layer ACTL, a second metal layer MTL2 located on the gate insulating layer GI, and a passivation layer PV covering the second metal layer MTL2.

The pixels SP may include first to third pixels SP1, SP2, and SP3. The pixel circuits of the first pixel SP1, the second pixel SP2, and the third pixel SP3 may be arranged in the opposite direction of the second direction DR2, but the arrangement direction of the pixel circuits is not limited thereto.

The first voltage line VDL may extend in the second direction DR2. The first voltage line VDL may be located on the left side of the pixel circuits of the first to third pixels SP1, SP2 and SP3 in a plan view. The first voltage line VDL may be located in a first metal layer MTL1 on the first substrate 110. The first voltage line VDL may overlap a first connection electrode CE1 and a fifth connection electrode CE5 of the second metal layer MTL2.

The first connection electrode CE1 and the fifth connection electrode CE5 may extend in the first direction DR1 and the second direction DR2. The first connection electrode CE1 and the fifth connection electrode CE5 may be located on the second metal layer MTL2. The first connection electrode CE1 and the fifth connection electrode CE5 may be connected to the first voltage line VDL. The first voltage line VDL may reduce line resistance by being connected to the first connection electrode CE1 and the fifth connection electrode CE5.

The first connection electrode CE1 may be connected to a first drain electrode DE1 of the first transistor ST1 of the first pixel SP1. Accordingly, the first voltage line VDL may supply a driving voltage to the first pixel SP1 through the first connection electrode CE1.

The fifth connection electrode CE5 may be connected to the first drain electrode DE1 of the first transistor ST1 of each of the second pixel SP2 and the third pixel SP3. Accordingly, the first voltage line VDL may supply a driving voltage to the second pixel SP2 and the third pixel SP3 through the fifth connection electrode CE5.

The first voltage line VDL may be connected to the horizontal voltage line HVDL to supply a driving voltage.

The horizontal voltage line HVDL may extend in the first direction DR1. The horizontal voltage line HVDL may be located on the upper side of the first gate line GL1 in a plan view. The horizontal voltage line HVDL may be located in the second metal layer MTL2. The horizontal voltage line HVDL may be connected to the first voltage line VDL to receive the driving voltage.

The initialization voltage line VIL may extend in the second direction DR2. The initialization voltage line VIL may be located on the left side of the first voltage line VDL in a plan view. The initialization voltage line VIL may be located in the first metal layer MTL1. The initialization voltage line VIL may overlap a second auxiliary electrode AUE2 of the second metal layer MTL2 and may be connected to the second auxiliary electrode AUE2. The initialization voltage line VIL may reduce line resistance by being connected to the second auxiliary electrode AUE2.

The second auxiliary electrode AUE2 may extend in the second direction DR2. The second auxiliary electrode AUE2 may be located on the second metal layer MTL2. The second auxiliary electrode AUE2 may be connected to a third source electrode SE3 of the third transistor ST3 of each of the first to third pixels SP1, SP2, and SP3. Accordingly, the initialization voltage line VIL may supply an initialization voltage to the third transistor ST3 of each of the first to third pixels SP1, SP2, and SP3 through the second auxiliary electrode AUE2, and may receive a sensing signal from the third transistor ST3.

The vertical voltage line VVSL may extend in the second direction DR2. The vertical voltage line VVSL may be located on the left side of the initialization voltage line VIL in a plan view. The vertical voltage line VVSL may be located in the first metal layer MTL1. The vertical voltage line VVSL may overlap the first auxiliary electrode AUE1 of the second metal layer MTL2.

The first auxiliary electrode AUE1 may extend in the second direction DR2. The first auxiliary electrode AUE1 may be located on the second metal layer MTL2. The first auxiliary electrode AUE1 may be connected to the vertical voltage line VVSL. The vertical voltage line VVSL may reduce line resistance by being connected to the first auxiliary electrode AUE1.

The first auxiliary electrode AUE1 may be connected to a common electrode auxiliary electrode VCE. Although not shown in the drawing, the common electrode auxiliary electrode (VCE) may be connected to the common electrode (CME). Accordingly, the vertical voltage line VVSL may supply a low potential voltage to the common electrode CME through the first auxiliary electrode AUE1 and the common electrode auxiliary electrode VCE.

The vertical voltage line VVSL may be connected to the second voltage line VSL to supply a low potential voltage to the second voltage line VSL.

The second voltage line VSL may extend in the first direction DR1. The second voltage line VSL may be located on the lower side of the second gate line GL2 in a plan view. The second voltage line VSL may be located in the third metal layer MTL3. The second voltage line VSL may receive a low potential voltage from the vertical voltage line VVSL.

The first gate line GL1 may be located on the upper side of the pixel circuit of the second pixel SP2 in a plan view. The first gate line GL1 may be located on the second metal layer MTL2. The first gate line GL1 may include an auxiliary line branched from the right sides of the first to third pixels SP1, SP2, and SP3 and extending in the opposite direction of the second direction DR2.

The auxiliary line of the first gate line GL1 may protrude from the first gate line GL1 in the opposite direction of the second direction DR2 in a plan view. The auxiliary line of the first gate line GL1 may be located on the right side of the pixel circuits of the first to third pixels SP1, SP2 and SP3 in a plan view. That is, the auxiliary line of the first gate line GL1 may be located between the first to third pixels SP1, SP2, and SP3 and the data line DL in a plan view. The first gate line GL1 may supply the first gate signal to the second transistor ST2 of each of the first to third pixels SP1, SP2, and SP3 through the auxiliary line.

The second gate line GL2 may be located on the lower side of the pixel circuit of the third pixel SP3 in a plan view. The second gate line GL2 may be located on the second metal layer MTL2. The second gate line GL2 may include an auxiliary line branched from the left side of the first voltage line VDL and extending in the second direction DR2.

The auxiliary line of the second gate line GL2 may protrude from the second gate line GL2 in the second direction DR2 in a plan view. The auxiliary line of the second gate line GL2 may be located on the left side of the first voltage line VDL in a plan view. That is, the auxiliary line of the second gate line GL2 may be located between the initialization voltage line VIL and the first voltage line VDL in a plan view. The second gate line GL2 may supply the second gate signal to the third transistor ST3 of each of the first to third pixels SP1, SP2, and SP3 through the auxiliary line.

The data lines DL may include first to third data lines DL1, DL2, and DL3. Each of the first to third data lines DL1, DL2, and DL3 may extend in the second direction DR2.

The second data line DL2 may be located on the right side of the auxiliary line of the first gate line GL1 in a plan view. The second data line DL2 may be located in the first metal layer MTL1. A sixth connection electrode CE6 of the second metal layer MTL2 may electrically connect the second data line DL2 to a second drain electrode DE2 of the second transistor ST2 of the second pixel SP2. Accordingly, the second data line DL2 may supply a data voltage to the second transistor ST2 of the second pixel SP2 through the sixth connection electrode CE6.

The third data line DL3 may be located on the right side of the second data line DL2 in a plan view. The third data line DL3 may be located in the first metal layer MTL1. An eighth connection electrode CE8 of the second metal layer MTL2 may electrically connect the third data line DL3 to the second drain electrode DE2 of the second transistor ST2 of the third pixel SP3. Accordingly, the third data line DL3 may supply a data voltage to the second transistor ST2 of the third pixel SP3 through the eighth connection electrode CE8.

The first data line DL1 may be located on the right side of the third data line DL3 in a plan view. The first data line DL1 may be located in the first metal layer MTL1. The second connection electrode CE2 of the second metal layer MTL2 may electrically connect the first data line DL1 to the second drain electrode DE2 of the second transistor ST2 of the first pixel SP1. Accordingly, the first data line DL1 may supply a data voltage to the second transistor ST2 of the first pixel SP1 through the second connection electrode CE2.

The pixel circuit of the first pixel SP1 may include first to third transistors ST1, ST2 and ST3.

The first transistor ST1 of the first pixel SP1 may include a first active region ACT1, a first upper gate electrode UGE1, a first lower gate electrode BGE1, the first drain electrode DE1, and the first source electrode SE1.

The first active region ACT1 of the first transistor ST1 may be located on the active layer ACTL and may overlap the first upper gate electrode UGE1 of the first transistor ST1.

The first upper gate electrode UGE1 of the first transistor ST1 may be located on the second metal layer MTL2. The first upper gate electrode UGE1 of the first transistor ST1 may be connected to the first capacitor electrode CPE1 of the first capacitor C1 through an extension portion. The first upper gate electrode UGE1 of the first transistor ST1 may be electrically connected to the second source SE2 of the second transistor ST2 through the first capacitor electrode CPE1 of the first capacitor C1 and the third connection electrode CE3.

The first lower gate electrode BGE1 of the first transistor ST1 may be located on the first metal layer MTL1. The first lower gate electrode BGE1 of the first transistor ST1 may be connected to the fourth connection electrode CE4. The first lower gate electrode BGE1 of the first transistor ST1 may be electrically connected to the first source electrode SE1 of the first transistor ST1 and the third drain electrode DE3 of the third transistor ST3 through the fourth connection electrode CE4. That is, the first lower gate electrode BGE1 of the first transistor ST1 may be electrically connected to the second node N2.

The first drain electrode DE1 and the first source electrode SE1 of the first transistor ST1 may be made conductive by heat treatment of the active layer ACTL. The first drain electrode DE1 and the first source electrode SE1 of the first transistor ST1 may be made conductive as an N-type semiconductor, but the present disclosure is not limited thereto.

The first drain electrode DE1 of the first transistor ST1 may be electrically connected to the first voltage line VDL through the first connection electrode CE1. The first connection electrode CE1 may be connected to the first voltage line VDL. Accordingly, the first drain electrode DE1 of the first transistor ST1 may receive the driving voltage from the first voltage line VDL.

The first source electrode SE1 of the first transistor ST1 may be a part of the second capacitor electrode CPE2 of the first capacitor C1. Accordingly, the first capacitor C1 may be formed between the first source electrode SE1 of the first transistor ST1, which is the second capacitor electrode CPE2, and the first capacitor electrode CPE1.

The first source electrode SE1 (or the second capacitor electrode CPE2) of the first transistor ST1 may be electrically connected to the light emitting element ED of the first pixel SP1. Accordingly, the first source electrode SE1 of the first transistor ST1 may supply a driving current to the light emitting element ED.

The second transistor ST2 of the first pixel SP1 may include a second active region ACT2, a second gate electrode GE2, a second drain electrode DE2, and a second source electrode SE2.

The second active region ACT2 of the second transistor ST2 may be located on the active layer ACTL and may overlap the second gate electrode GE2 of the second transistor ST2.

The second gate electrode GE2 of the second transistor ST2 may be located in the second metal layer MTL2. The second gate electrode GE2 of the second transistor ST2 may be a part of the auxiliary line of the first gate line GL1.

The second drain electrode DE2 and the second source electrode SE2 of the second transistor ST2 may be made conductive by heat treatment of the active layer ACTL. The second drain electrode DE2 and the second source electrode SE2 of the second transistor ST2 may be made conductive as an N-type semiconductor, but the present disclosure is not limited thereto.

The second drain electrode DE2 of the second transistor ST2 may be connected to the second connection electrode CE2 of the second metal layer MTL2. The second drain electrode DE2 of the second transistor ST2 may be electrically connected to the first data line DL1 through the second connection electrode CE2 of the second metal layer MTL2. Accordingly, the first data line DL1 may supply a data voltage to the second transistor ST2 of the first pixel SP1 through the second connection electrode CE2.

The second source electrode SE2 of the second transistor ST2 may be connected to the third connection electrode CE3 of the second metal layer MTL2. The second source electrode SE2 of the second transistor ST2 may be electrically connected to the first capacitor electrode CPE1 of the first capacitor C1 located on the first metal layer MTL1 through the third connection electrode CE3. The first capacitor electrode CPE1 may be connected to the first upper gate electrode UGE1 of the first transistor ST1. Accordingly, the second source electrode SE2 of the second transistor ST2 may supply a first gate voltage to the first transistor ST1 through the third connection electrode CE3 and the first capacitor electrode CPE1.

The third transistor ST3 of the first pixel SP1 may include a third active region ACT3, a third gate electrode GE3, a third drain electrode DE3, and a third source electrode SE3.

The third active region ACT3 of the third transistor ST3 may be located on the active layer ACTL, and may overlap the third gate electrode GE3 of the third transistor ST3.

The third gate electrode GE3 of the third transistor ST3 may be located in the second metal layer MTL2. The third gate electrode GE3 of the third transistor ST3 may be a part of the auxiliary line of the second gate line GL2.

The third drain electrode DE3 and the third source electrode SE3 of the third transistor ST3 may be made conductive by heat treatment of the active layer ACTL. The third drain electrode DE3 and the third source electrode SE3 of the third transistor ST3 may be made conductive as an N-type semiconductor, but the present disclosure is not limited thereto.

The third drain electrode DE3 of the third transistor ST3 may be connected to the fourth connection electrode CE4 of the second metal layer MTL2. The third drain electrode DE3 of the third transistor ST3 may be electrically connected to the first source electrode SE1 of the first transistor ST1 and the second capacitor electrode CPE2 of the first capacitor C1 through the fourth connection electrode CE4. The third drain electrode DE3 of the third transistor ST3 may be electrically connected to the first lower gate electrode BGE1 of the first transistor ST1 through the fourth connection electrode CE4.

The third source electrode SE3 of the third transistor ST3 may be connected to the second auxiliary electrode AUE2 of the second metal layer MTL2. The third source electrode SE3 of the third transistor ST3 may be electrically connected to the initialization voltage line VIL through the second auxiliary electrode AUE2. The third source electrode SE3 of the third transistor ST3 may receive the initialization voltage from the initialization voltage line VIL. The third source electrode SE3 of the third transistor ST3 may supply the sensing signal to the initialization voltage line VIL.

The pixel circuit of the second pixel SP2 may include first to third transistors ST1, ST2, and ST3.

The first transistor ST1 of the second pixel SP2 may include the first active region ACT1, the first upper gate electrode UGE1, the first lower gate electrode BGE1, the first drain electrode DE1, and the first source electrode SE1.

The first active region ACT1 of the first transistor ST1 may be located on the active layer ACTL and may overlap the first upper gate electrode UGE1 of the first transistor ST1.

The first upper gate electrode UGE1 of the first transistor ST1 may be located on the second metal layer MTL2. The first upper gate electrode UGE1 of the first transistor ST1 may be connected to the first capacitor electrode CPE1 of the first capacitor C1 and the second source electrode SE2 of the second transistor ST2 through the extension portion.

The first lower gate electrode BGE1 of the first transistor ST1 may be located on the first metal layer MTL1. The first lower gate electrode BGE1 of the first transistor ST1 may be connected to a seventh connection electrode CE7. The first lower gate electrode BGE1 of the first transistor ST1 may be electrically connected to the first source electrode SE1 of the first transistor ST1 and the third drain electrode DE3 of the third transistor ST3 through the seventh connection electrode CE7. That is, the first lower gate electrode BGE1 of the first transistor ST1 may be electrically connected to the second node N2.

The first drain electrode DE1 and the first source electrode SE1 of the first transistor ST1 may be made conductive by heat treatment of the active layer ACTL. The first drain electrode DE1 and the first source electrode SE1 of the first transistor ST1 may be made conductive as an N-type semiconductor, but the present disclosure is not limited thereto.

The first drain electrode DE1 of the first transistor ST1 may be electrically connected to the first voltage line VDL through a drain connection portion DCP and the fifth connection electrode CE5. The fifth connection electrode CE5 may be connected to the first voltage line VDL. The drain connection portion DCP may be connected to the fifth connection electrode CE5. The drain connection portion DCP may be located between the first drain electrode DE1 of the first transistor ST1 of the second pixel SP2 and the first drain electrode DE1 of the first transistor ST1 of the third pixel SP3, and may supply a driving voltage to each of the two first drain electrodes DE1. Accordingly, the first drain electrode DE1 of the first transistor ST1 may receive the driving voltage from the first voltage line VDL through the drain connection portion DCP and the fifth connection electrode CE5.

The first source electrode SE1 of the first transistor ST1 may be a part of the second capacitor electrode CPE2 of the first capacitor C1. Accordingly, the first capacitor C1 may be formed between the first source electrode SE1 of the first transistor ST1, which is the second capacitor electrode CPE2, and the first capacitor electrode CPE1.

The first source electrode SE1 (or the second capacitor electrode CPE2) of the first transistor ST1 may be electrically connected to the light emitting element ED of the second pixel SP2. Accordingly, the first source electrode SE1 of the first transistor ST1 may supply a driving current to the light emitting element ED.

The second transistor ST2 of the second pixel SP2 may include a second active region ACT2, a second gate electrode GE2, a second drain electrode DE2, and a second source electrode SE2.

The second active region ACT2 of the second transistor ST2 may be located on the active layer ACTL and may overlap the second gate electrode GE2 of the second transistor ST2.

The second gate electrode GE2 of the second transistor ST2 may be located in the second metal layer MTL2. The second gate electrode GE2 of the second transistor ST2 may be a part of the auxiliary line of the first gate line GL1.

The second drain electrode DE2 and the second source electrode SE2 of the second transistor ST2 may be made conductive by heat treatment of the active layer ACTL. The second drain electrode DE2 and the second source electrode SE2 of the second transistor ST2 may be made conductive as an N-type semiconductor, but the present disclosure is not limited thereto.

The second drain electrode DE2 of the second transistor ST2 may be connected to the sixth connection electrode CE6 of the second metal layer MTL2. The second drain electrode DE2 of the second transistor ST2 may be electrically connected to the second data line DL2 through the sixth connection electrode CE6 of the second metal layer MTL2. Accordingly, the second data line DL2 may supply a data voltage to the second transistor ST2 of the second pixel SP2 through the sixth connection electrode CE6.

The second source electrode SE2 of the second transistor ST2 may be connected to the extension portion of the first upper gate electrode UGE1 of the first transistor ST1. Accordingly, the second source electrode SE2 of the second transistor ST2 may supply the first gate voltage to the first transistor ST1. The second source electrode SE2 of the second transistor ST2 may be connected to the first capacitor electrode CPE1 of the first capacitor C1 through the extension portion of the first upper gate electrode UGE1 of the first transistor ST1.

The third transistor ST3 of the second pixel SP2 may include a third active region ACT3, a third gate electrode GE3, a third drain electrode DE3, and a third source electrode SE3.

The third active region ACT3 of the third transistor ST3 may be located on the active layer ACTL, and may overlap the third gate electrode GE3 of the third transistor ST3.

The third gate electrode GE3 of the third transistor ST3 may be located in the second metal layer MTL2. The third gate electrode GE3 of the third transistor ST3 may be a part of the auxiliary line of the second gate line GL2.

The third drain electrode DE3 and the third source electrode SE3 of the third transistor ST3 may be made conductive by heat treatment of the active layer ACTL. The third drain electrode DE3 and the third source electrode SE3 of the third transistor ST3 may be made conductive as an N-type semiconductor, but the present disclosure is not limited thereto.

The third drain electrode DE3 of the third transistor ST3 may be electrically connected to the first source electrode SE1 of the first transistor ST1 and the second capacitor electrode CPE2 of the first capacitor C1. The third drain electrode DE3 of the third transistor ST3 may be part of the first source electrode SE1 of the first transistor ST1 and the second capacitor electrode CPE2 of the first capacitor C1. The third drain electrode DE3 of the third transistor ST3 may be electrically connected to the first lower gate electrode BGE1 of the first transistor ST1 through the seventh connection electrode CE7.

The third source electrode SE3 of the third transistor ST3 may be connected to the second auxiliary electrode AUE2 of the second metal layer MTL2. The third source electrode SE3 of the third transistor ST3 may be electrically connected to the initialization voltage line VIL through the second auxiliary electrode AUE2. The third source electrode SE3 of the third transistor ST3 may receive the initialization voltage from the initialization voltage line VIL. The third source electrode SE3 of the third transistor ST3 may supply the sensing signal to the initialization voltage line VIL.

The pixel circuit of the third pixel SP3 may include first to third transistors ST1, ST2 and ST3.

The first transistor ST1 of the third pixel SP3 may include the first active region ACT1, the first upper gate electrode UGE1, the first lower gate electrode BGE1, the first drain electrode DE1, and the first source electrode SE1.

The first active region ACT1 of the first transistor ST1 may be located on the active layer ACTL and may overlap the first upper gate electrode UGE1 of the first transistor ST1.

The first upper gate electrode UGE1 of the first transistor ST1 may be located on the second metal layer MTL2. The first upper gate electrode UGE1 of the first transistor ST1 may be connected to the first capacitor electrode CPE1 of the first capacitor C1 and the second source electrode SE2 of the second transistor ST2 through the extension portion.

The first lower gate electrode BGE1 of the first transistor ST1 may be located on the first metal layer MTL1. The first lower gate electrode BGE1 of the first transistor ST1 may be connected to a ninth connection electrode CE9. The first lower gate electrode BGE1 of the first transistor ST1 may be electrically connected to the first source electrode SE1 of the first transistor ST1 and the third drain electrode DE3 of the third transistor ST3 through the ninth connection electrode CE9. That is, the first lower gate electrode BGE1 of the first transistor ST1 may be electrically connected to the second node N2.

The first drain electrode DE1 and the first source electrode SE1 of the first transistor ST1 may be made conductive by heat treatment of the active layer ACTL. The first drain electrode DE1 and the first source electrode SE1 of the first transistor ST1 may be made conductive as an N-type semiconductor, but the present disclosure is not limited thereto.

The first drain electrode DE1 of the first transistor ST1 may be electrically connected to the first voltage line VDL through a drain connection portion DCP and the fifth connection electrode CE5. The fifth connection electrode CE5 may be connected to the first voltage line VDL. The drain connection portion DCP may be connected to the fifth connection electrode CE5. The drain connection portion DCP may be located between the first drain electrode DE1 of the first transistor ST1 of the second pixel SP2 and the first drain electrode DE1 of the first transistor ST1 of the third pixel SP3, and may supply a driving voltage to each of the two first drain electrodes DE1. Accordingly, the first drain electrode DE1 of the first transistor ST1 may receive the driving voltage from the first voltage line VDL through the drain connection portion DCP and the fifth connection electrode CE5.

The first source electrode SE1 of the first transistor ST1 may be a part of the second capacitor electrode CPE2 of the first capacitor C1. Accordingly, the first capacitor C1 may be formed between the first source electrode SE1 of the first transistor ST1, which is the second capacitor electrode CPE2, and the first capacitor electrode CPE1.

The first source electrode SE1 (or the second capacitor electrode CPE2) of the first transistor ST1 may be electrically connected to the light emitting element ED of the third pixel SP3. Accordingly, the first source electrode SE1 of the first transistor ST1 may supply a driving current to the light emitting element ED.

The second transistor ST2 of the third pixel SP3 may include a second active region ACT2, a second gate electrode GE2, a second drain electrode DE2, and a second source electrode SE2.

The second active region ACT2 of the second transistor ST2 may be located on the active layer ACTL and may overlap the second gate electrode GE2 of the second transistor ST2.

The second gate electrode GE2 of the second transistor ST2 may be located in the second metal layer MTL2. The second gate electrode GE2 of the second transistor ST2 may be a part of the auxiliary line of the first gate line GL1.

The second drain electrode DE2 and the second source electrode SE2 of the second transistor ST2 may be made conductive by heat treatment of the active layer ACTL. The second drain electrode DE2 and the second source electrode SE2 of the second transistor ST2 may be made conductive as an N-type semiconductor, but the present disclosure is not limited thereto.

The second drain electrode DE2 of the second transistor ST2 may be connected to the eighth connection electrode CE8 of the second metal layer MTL2. The second drain electrode DE2 of the second transistor ST2 may be electrically connected to the third data line DL3 through the eighth connection electrode CE8 of the second metal layer MTL2. Accordingly, the third data line DL3 may supply a data voltage to the second transistor ST2 of the third pixel SP3 through the eighth connection electrode CE8.

The second source electrode SE2 of the second transistor ST2 may be connected to the extension portion of the first upper gate electrode UGE1 of the first transistor ST1. Accordingly, the second source electrode SE2 of the second transistor ST2 may supply the first gate voltage to the first transistor ST1. The second source electrode SE2 of the second transistor ST2 may be connected to the first capacitor electrode CPE1 of the first capacitor C1 through the extension portion of the first upper gate electrode UGE1 of the first transistor ST1.

The third transistor ST3 of the third pixel SP3 may include a third active region ACT3, a third gate electrode GE3, a third drain electrode DE3, and a third source electrode SE3.

The third active region ACT3 of the third transistor ST3 may be located on the active layer ACTL, and may overlap the third gate electrode GE3 of the third transistor ST3.

The third gate electrode GE3 of the third transistor ST3 may be located in the second metal layer MTL2. The third gate electrode GE3 of the third transistor ST3 may be a part of the auxiliary line of the second gate line GL2.

The third drain electrode DE3 and the third source electrode SE3 of the third transistor ST3 may be made conductive by heat treatment of the active layer ACTL. The third drain electrode DE3 and the third source electrode SE3 of the third transistor ST3 may be made conductive as an N-type semiconductor, but the present disclosure is not limited thereto.

The third drain electrode DE3 of the third transistor ST3 may be electrically connected to the first source electrode SE1 of the first transistor ST1 and the second capacitor electrode CPE2 of the first capacitor C1. The third drain electrode DE3 of the third transistor ST3 may be part of the first source electrode SE1 of the first transistor ST1 and the second capacitor electrode CPE2 of the first capacitor C1. The third drain electrode DE3 of the third transistor ST3 may be electrically connected to the first lower gate electrode BGE1 of the first transistor ST1 through the ninth connection electrode CE9.

The third source electrode SE3 of the third transistor ST3 may be connected to the second auxiliary electrode AUE2 of the second metal layer MTL2. The third source electrode SE3 of the third transistor ST3 may be electrically connected to the initialization voltage line VIL through the second auxiliary electrode AUE2. The third source electrode SE3 of the third transistor ST3 may receive the initialization voltage from the initialization voltage line VIL. The third source electrode SE3 of the third transistor ST3 may supply the sensing signal to the initialization voltage line VIL.

The light emitting element layer EML may be located on the circuit layer CCL. The light emitting element layer EML may include the third metal layer MTL3 located on the passivation layer PV, the pixel defining layer PDL located on the third metal layer MTL3 and the passivation layer PV, the light emitting layer LEL located on the third metal layer MTL3 and the pixel defining layer PDL, and the common electrode CME located on the light emitting layer LEL.

The third metal layer MTL3 may be located on the passivation layer PV. The third metal layer MTL3 may include the first pixel electrode PXR of the first pixel SP1, the second pixel electrode PXG of the second pixel SP2, the third pixel electrode PXB of the third pixel SP3, and the common electrode auxiliary electrode VCE.

The first pixel electrode PXR of the first pixel SP1 may be located substantially on the left side and the upper side of the pixel circuit of the first pixel SP1 in a plan view. For example, the first pixel electrode PXR may overlap the vertical voltage line VVSL, the initialization voltage line VIL, the first voltage line VDL, and the first gate line GL1 in the third direction DR3. The first pixel electrode PXR may be positioned at the upper left portion of the second pixel electrode PXG.

The first pixel electrode PXR may extend in the first direction DR1 and the second direction DR2. For example, the first pixel electrode PXR may include a main portion overlapping the first emission area LA1 and a protrusion portion protruding from the main portion in the first direction DR1.

The other end of the main portion of the first pixel electrode PXR in the second direction DR2 may overlap the first capacitor C1 of the second pixel SP2 in the first direction DR1. One end of the protrusion portion of the first pixel electrode PXR in the first direction DR1 may overlap the auxiliary line of the first gate line GL1.

The first pixel electrode PXR may be connected to the first source electrode SE1 of the first transistor ST1 of the first pixel SP1 through a contact hole overlapping the protrusion portion. The first pixel electrode PXR may receive the driving voltage from the first voltage line VDL through the first source electrode SE1 of the first transistor ST1 of the first pixel SP1.

The second pixel electrode PXG of the second pixel SP2 may be located substantially at the center of the pixel circuit of the second pixel SP2 in a plan view. For example, the second pixel electrode PXG may overlap the pixel circuit of the first pixel SP1, the pixel circuit of the second pixel SP2, and the pixel circuit of the third pixel SP3 in the third direction DR3. The second pixel electrode PXG may be located between the first pixel electrode PXR and the third pixel electrode PXB.

The second pixel electrode PXG may extend in the diagonal direction defined by the first direction DR1 and the second direction DR2. One end of the second pixel electrode PXG in the diagonal direction indicated by the first direction DR1 and the second direction DR2 may overlap the first capacitor C1 of the first pixel SP1 in the third direction DR3. The other end of the second pixel electrode PXG in the diagonal direction indicated by the opposite direction of the first direction DR1 and the opposite direction of the second direction DR2 may overlap the first capacitor C1 of the third pixel SP3 in the third direction DR3.

The second pixel electrode PXG may be connected to the first source electrode SE1 of the first transistor ST1 of the second pixel SP2 through a contact hole located at the center of the second pixel electrode PXG. The second pixel electrode PXG may receive the driving voltage from the first voltage line VDL through the first source electrode SE1 of the first transistor ST1 of the second pixel SP2.

The third pixel electrode PXB of the third pixel SP3 may be located substantially on the right side and the lower side of the pixel circuit of the third pixel SP3 in a plan view. For example, the third pixel electrode PXB may overlap the data line DL in the third direction DR3. The third pixel electrode PXB may be positioned at the lower right portion of the second pixel electrode PXG.

The third pixel electrode PXB may extend in the first direction DR1 and the second direction DR2. One end of the third pixel electrode PXB in the second direction DR2 may overlap the first capacitor C1 of the second pixel SP2 in the first direction DR1. The other end of the third pixel electrode PXB in the first direction DR1 may overlap the first transistors ST1 of the second pixel SP2 and the third pixel SP3.

The third pixel electrode PXB may be connected to the first source electrode SE1 of the first transistor ST1 of the third pixel SP3 through a contact hole adjacent to the other end of the third pixel electrode PXB in the first direction DR1. The third pixel electrode PXB may receive the driving voltage from the first voltage line VDL through the first source electrode SE1 of the first transistor ST1 of the third pixel SP3.

The pixel defining layer PDL may be located on the passivation layer PV of the circuit layer CCL and the third metal layer MTL3. The pixel defining layer PDL may electrically insulate the patterned third metal layer MTL3. The pixel defining layer PDL may include a plurality of open portions. Some of the plurality of open portions may expose a part of the third metal layer MTL3. The pixel electrode PXE of the third metal layer MTL3 may be in contact with the light emitting layer LEL through the plurality of open portions.

The emission area LA may be defined by the open portion of the pixel defining layer PDL. For example, the first emission area LA1 may be defined by the open portion of the pixel defining layer PDL overlapping the first pixel electrode PXR, the second emission area LA2 may be defined by the open portion of the pixel defining layer PDL overlapping the second pixel electrode PXG, and the third emission area LA3 may be defined by the open portion of the pixel defining layer PDL overlapping the third pixel electrode PXB. The first to third emission areas LA1, LA2, and LA3 may have sizes smaller than those of the first to third pixel electrodes PXR, PXG, and PXB, respectively.

The first emission area LA1 may be located substantially on the left side and the upper side of the pixel circuit of the first pixel SP1 in a plan view. The first emission area LA1 may overlap the main portion of the first pixel electrode PXR. The second emission area LA2 may be located substantially at the center of the pixel circuit of the second pixel SP2 in a plan view. The second emission area LA2 may overlap most of the second pixel electrode PXG. The third emission area LA3 may be located substantially on the right side and the lower side of the pixel circuit of the third pixel SP3 in a plan view. The third emission area LA3 may overlap most of the third pixel electrode PXB.

Each of contact holes through which each of the first to third pixel electrodes PXR, PXG, and PXB is in contact with the first source electrode SE1 of the first transistor ST1 may not overlap the open portion of the pixel defining layer PDL.

Because the light emitting layer LEL and the common electrode CME have already been described, the description thereof will be omitted.

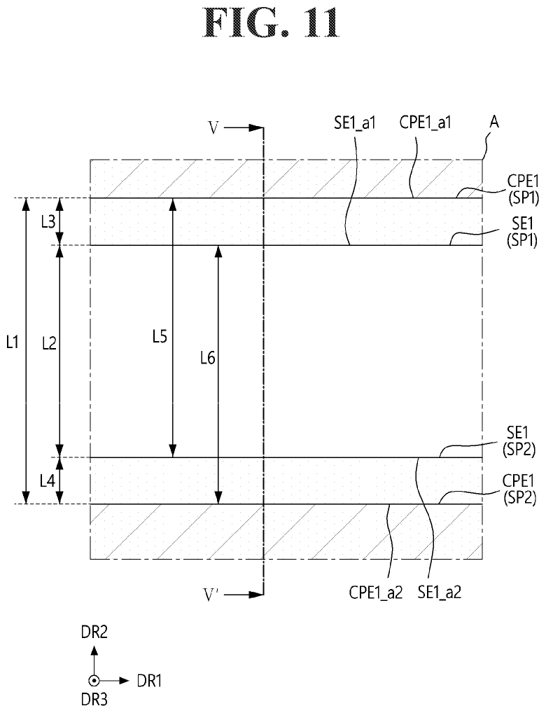

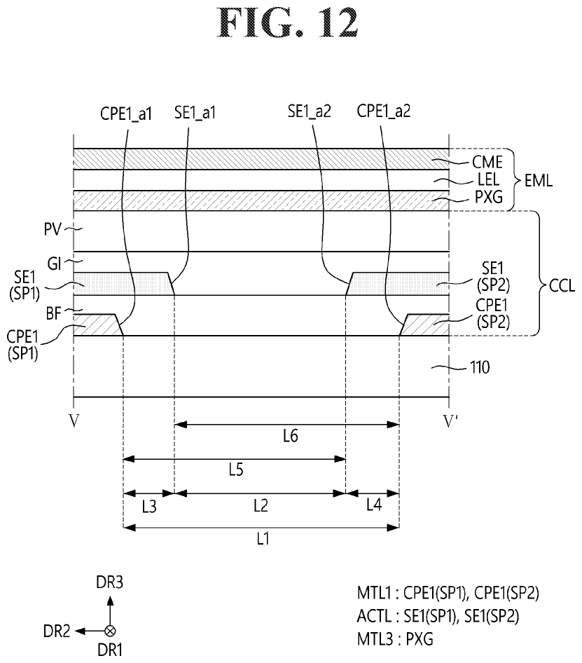

FIG. 11 is an enlarged view of the area A of FIG. 8. FIG. 12 is a cross-sectional view taken along the line V-V′ of FIG. 11.

Referring to FIGS. 11 and 12 in addition to FIG. 8, the first capacitor electrode CPE1 of the first pixel SP1 and the first capacitor electrode CPE1 of the second pixel SP2 may be located adjacent to each other. Further, the second capacitor electrode CPE2 of the first pixel SP1 and the second capacitor electrode CPE2 of the second pixel SP2 may be located adjacent to each other. That is, the first source electrode SE1 of the first pixel SP1 and the first source electrode SE1 of the second pixel SP2 may be located adjacent to each other.

Hereinafter, the second capacitor electrode CPE2 of the first pixel SP1 and the second capacitor electrode CPE2 of the second pixel SP2 will be referred to and described as the first source electrode SE1 of the first pixel SP1 and the second source electrode SE1 of the second pixel SP2, respectively, because each of the second capacitor electrode CPE2 of the first pixel SP1 and the second capacitor electrode CPE2 of the second pixel SP2 is a part of the first source electrode SE1 of the first transistor ST1.

In area A of the drawing, a first end SE1_a1 that is one end of the first source electrode SE1 of the first pixel SP1 and a second end SE1_a2 that is one end of the first source electrode SE1 of the second pixel SP2 may face each other. A third end CPE1_a1 that is one end of the first capacitor electrode CPE1 of the first pixel SP1 and a fourth end CPE1_a2 that is one end of the first capacitor electrode CPE1 of the second pixel SP2 may face each other.

The first end SE1_a1 may be an end adjacent to the second pixel SP2 among the ends of the first source electrode SE1 of the first pixel SP1. The second end SE1_a2 may be an end adjacent to the first pixel SP1 among the ends of the first source electrode SE1 of the second pixel SP2. The third end CPE1_a1 may be an end adjacent to the second pixel SP2 among the ends of the first capacitor electrode CPE1 of the first pixel SP1. The fourth end CPE1_a2 may be an end adjacent to the first pixel SP1 among the ends of the first capacitor electrode CPE1 of the second pixel SP2.

The first end SE1_a1 may be located between the third end CPE1_a1 and the fourth end CPE1_a2. The second end SE1_a2 may be located between the third end CPE1_a1 and the fourth end CPE1_a2. For example, a distance L2 between the first end SE1_a1 and the second end SE1_a2 may be smaller than a distance L5 between the second end SE1_a2 and the third end CPE1_a1. The distance L2 between the first end SE1_a1 and the second end SE1_a2 may be smaller than a distance L6 between the first end SE1_a1 and the fourth end CPE1_a2.

A distance L1 between the third end CPE1_a1 and the fourth end CPE1_a2 may be greater than the distance L2 between the first end SE1_a1 and the second end SE1_a2. For example, the distance L1 between the third end CPE1_a1 and the fourth end CPE1_a2 may be approximately 15 μm to 17 μm. The distance L2 between the first end SE1_a1 and the second end SE1_a2 may be approximately 8 μm to 11 μm.

According to some embodiments, a distance L3 between the first end SE1_a1 and the third end CPE1_a1 may be the same as a distance L4 between the second end SE1_a2 and the fourth end CPE1_a2. For example, the distance L3 between the first end SE1_a1 and the third end CPE1_a1 and the distance L4 between the second end SE1_a2 and the fourth end CPE1_a2 may be approximately 1.5 μm to 6 μm.

According to some embodiments, the distance L3 between the first end SE1_a1 and the third end CPE1_a1 may be different from the distance L4 between the second end SE1_a2 and the fourth end CPE1_a2. For example, the distance L3 between the first end SE1_a1 and the third end CPE1_a1 may be approximately 3 μm to about 6 μm, and the distance L4 between the second end SE1_a2 and the fourth end CPE1_a2 may be approximately 1 μm to 2 μm.

The distances L1, L2, L3, L4, and L5 between the first to fourth ends SE1_a1, SE1_a2, CPE1_a1, and CPE1_a2 described above mean separation distances in a plan view or separation distances in the second direction DR2 in cross-sectional view.

When the first capacitor electrode CPE1 of the first pixel SP1 and the first capacitor electrode CEP1 of the second pixel SP2 are located adjacent to each other, they may affect each other. That is, because each of the first capacitor electrode CPE1 of the first pixel SP1 and the first capacitor electrode CPE1 of the second pixel SP2 is electrically connected to the first upper gate electrode UGE1, the first upper gate electrode UGE1 of the first pixel SP1 and the first upper gate electrode UGE1 of the second pixel SP2 adjacent to each other may affect each other.

For example, the driving voltage applied to the first upper gate electrode UGE1 of the first pixel SP1 may be coupled to the first upper gate electrode UGE1 of the second pixel SP2. Accordingly, a color step phenomenon in which light is emitted even in the second pixel SP2 to which no gate voltage is applied may occur.

Meanwhile, the first source electrode SE1 of the first pixel SP1 and the first source electrode SE1 of the second pixel SP2 respectively overlapping the first capacitor electrode CPE1 of the first pixel SP1 and the first capacitor electrode CPE1 of the second pixel SP2 may serve as shields to minimize a coupling phenomenon between the first capacitor electrode CPE1 of the first pixel SP1 and the first capacitor electrode CPE1 of the second pixel SP2 that are adjacent to each other.

In a display device 1 according to some embodiments, because each of the first end SE1_a1 and the second end SE1_a2 is located between the third end CPE1_a1 and the fourth end CPE1_a2, the shielding function of the first source electrode SE1 of the first pixel SP1 and the first source electrode SE1 of the second pixel SP2 that minimizes the coupling phenomenon between the first capacitor electrode CPE1 of the first pixel SP1 and the first capacitor electrode CPE1 of the second pixel SP2 that are adjacent to each other may be further improved.

Further, by securing a certain level of the distance L2 between the first source electrode SE1 of the first pixel SP1 and the first source electrode SE1 of the second pixel SP2, it may be possible to prevent or reduce instances of the coupling phenomenon between the first source electrode SE1 of the first pixel SP1 and the first source electrode SE1 of the second pixel SP2 that are adjacent to each other.

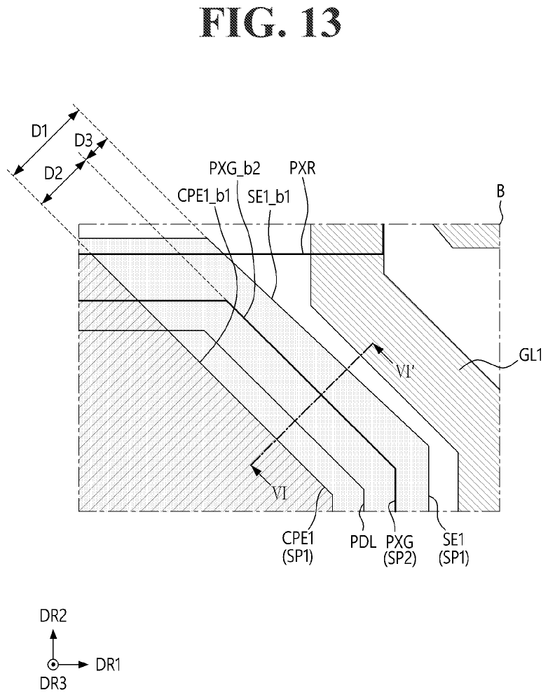

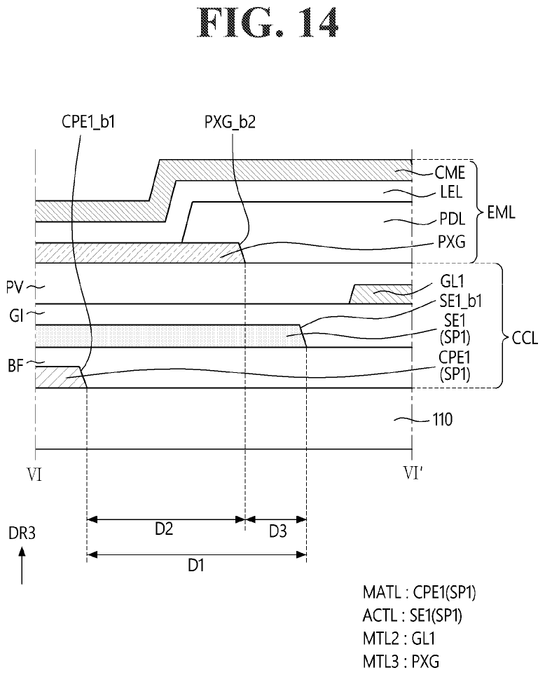

FIG. 13 is an enlarged view of the area B of FIG. 8. FIG. 14 is a cross-sectional view taken along the line VI-VI′ of FIG. 13.

Referring to FIGS. 13 and 14 in addition to FIG. 8, the second pixel electrode PXG of the second pixel SP2 may at least partially overlap the first source electrode SE1 of the first pixel SP1 and the first capacitor electrode CPE1 of the first pixel SP1. For example, one end of the second pixel electrode PXG of the second pixel SP2 in the second direction DR2 may overlap the first source electrode SE1 of the first pixel SP1 and the first capacitor electrode CPE1.

In the drawing, a fifth end SE1_b1 that is one end of the first source electrode SE1 of the first pixel SP1, a sixth end CPE1_b1 that is one end of the first capacitor electrode CPE1 of the first pixel SP1, and a seventh end PXG_b2 that is one end of the second pixel electrode PXG of the second pixel SP2 may face one another. For example, the fifth end SE1_b1, the sixth end CPE1_b1, and the seventh end PXG_b2 may extend side by side in the diagonal direction defined by the opposite direction of the first direction DR1 and the second direction DR2.

The fifth end SE1_b1 may be an end adjacent to the auxiliary line of the first gate line GL1 among the ends of the first source electrode SE1 of the first pixel SP1. The sixth end CPE1_b1 may be an end overlapping the second pixel electrode PXG of the second pixel SP2 among the ends of the first capacitor electrode CPE1 of the first pixel SP1. The seventh end PXG_b2 may be an end adjacent to the first pixel SP1 and the auxiliary line of the first gate line GL1 among the ends of the second pixel electrode PXG of the second pixel SP2.

The seventh end PXG_b2 may be located between the fifth end SE1_b1 and the sixth end CPE1_b1. For example, a distance D1 between the fifth end SE1_b1 and the sixth end CPE1_b1 may be greater than a distance D2 between the sixth end CPE1_b1 and the seventh end PXG_b2. For example, the distance D1 between the fifth end SE1_b1 and the sixth end CPE1_b1 may be approximately 7 μm to 12 μm.

According to some embodiments, the distance D2 between the sixth end CPE1_b1 and the seventh end PXG_b2 may be different from a distance D3 between the fifth end SE1_b1 and the seventh end PXG_b2. For example, the distance D2 between the sixth end CPE1_b1 and the seventh end PXG_b2 may be approximately 7 μm or less, and the distance D3 between the fifth end SE1_b1 and the seventh end PXG_b2 may be approximately 12 μm or less.

According to some embodiments, the distance D2 between the sixth end CPE1_b1 and the seventh end PXG_b2 may be the same as the distance D3 between the fifth end SE1_b1 and the seventh end PXG_b2. For example, the distance D2 between the sixth end CPE1_b1 and the seventh end PXG_b2 and the distance D3 between the fifth end SE1_b1 and the seventh end PXG_b2 may be approximately 3.5 μm to 6 μm.

The distances D1, D2, and D3 between the fifth to seventh ends SE1_b1, CPE1_b1, and PXG_b2 described above mean separation distances in a plan view or separation distances in the horizontal direction in cross-sectional view.

When the second pixel electrode PXG of the second pixel SP2 is arranged to overlap the first capacitor electrode CPE1 of the first pixel SP1, the first capacitor electrode CPE1 of the first pixel SP1 is electrically connected to the first upper gate electrode UGE1 of the first pixel SP1, and thus may affect the overlapping second pixel electrode PXG of the second pixel SP2.

For example, the driving voltage applied to the first upper gate electrode UGE1 of the first pixel SP1 may be coupled to the second pixel electrode PXG of the second pixel SP2. Accordingly, a color step phenomenon in which light is emitted even in the second pixel SP2 to which no driving voltage is applied may occur.

Meanwhile, the first source electrode SE1 of the first pixel SP1 overlapping the first capacitor electrode CPE1 of the first pixel SP1 may serve as a shield to minimize the coupling phenomenon between the first capacitor electrode CPE1 of the first pixel SP1 and the second pixel electrode PXG of the second pixel SP2 that are adjacent to each other.

In a display device 1 according to some embodiments, because the seventh end PXG_b2 is located between the fifth end SE1_b1 and the sixth end CPE1_b1, the first source electrode SE1 of the first pixel SP1 may serve as a shield to minimize the coupling phenomenon between the first capacitor electrode CPE1 of the first pixel SP1 and the second pixel electrode PXG of the second pixel SP2 that are adjacent to each other.

Further, due to the shielding function of the first source electrode SE1 of the first pixel SP1, the coupling phenomenon may be minimized even if the overlapping area between the first capacitor electrode CPE1 of the first pixel SP1 and the second pixel electrode PXG of the second pixel SP2 becomes larger, so that one end of the second pixel electrode PXG of the second pixel SP2 in the first direction DR1 may further extend toward the first direction DR1, and one end thereof in the second direction DR2 may further extend toward the second direction DR2. Accordingly, the distance in the first direction DR1 between one end of the second pixel electrode PXG of the second pixel SP2 in the first direction DR1 and one end of the first pixel electrode PXR of the first pixel SP1 in the first direction DR1 decreases, so that the edge discoloration in which a color other than white or black is displayed at the boundary between white and black may be minimized at the upper, lower, left, and right sides of the pixel.

Similarly, the distance in the second direction DR2 between one end of the second pixel electrode PXG of the second pixel SP2 in the second direction DR2 and one end of the first pixel electrode PXR of the first pixel SP1 in the second direction DR2 decreases, so that the edge discoloration may be minimized at the upper, lower, left and right sides of the pixel.

Hereinafter, further details of the display device according to some embodiments will be described. In the following embodiments, description of the same components as those of the above-described embodiments, which are denoted by like reference numerals, may be omitted or simplified, and differences will be mainly described.

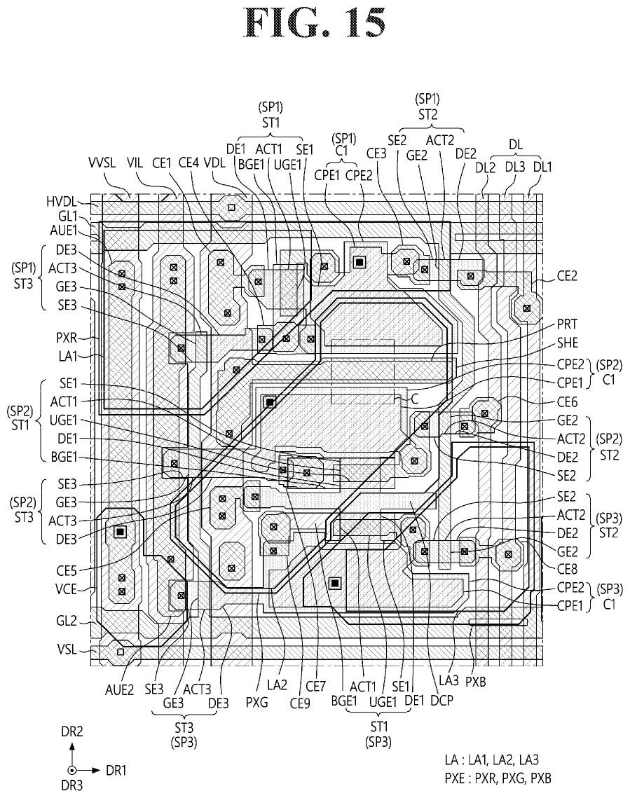

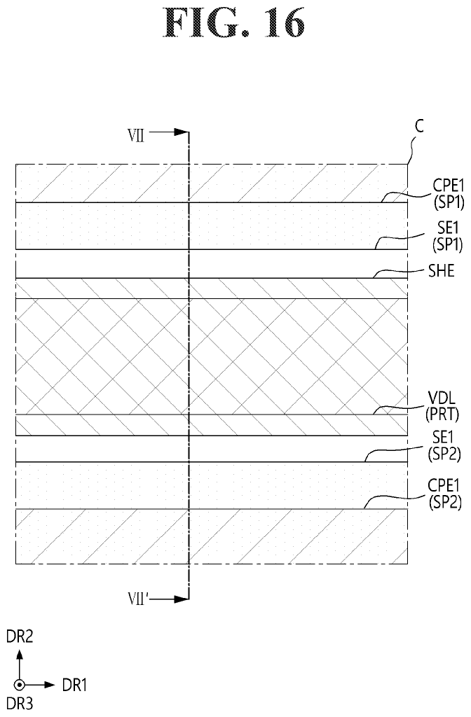

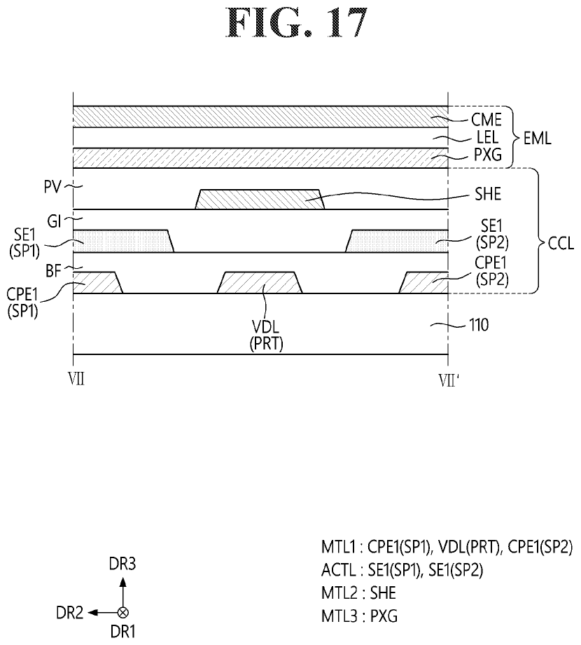

FIG. 15 is a layout diagram illustrating a thin film transistor layer and a light emitting element layer of a display device according to some embodiments. FIG. 16 is an enlarged view of the area C of FIG. 15. FIG. 17 is a cross-sectional view taken along the line VII-VII′ of FIG. 16.

Referring to FIGS. 15 to 17, the display device 1 is different from the display device 1 according to the embodiments described with reference to FIG. 8 or the like in that it further includes a shielding electrode SHE and a protrusion portion PRT of the first voltage line VDL.

For example, the display device 1 according to some embodiments may further include the shielding electrode SHE located on the second metal layer MTL2 and the protrusion portion PRT of the first voltage line VDL located on the first metal layer MTL1.

The first voltage line VDL may include a main portion extending in the second direction DR2 and the protrusion portion PRT protruding from the main portion in the first direction DR1.

The protrusion portion PRT may be located between the first pixel SP1 and the second pixel SP2. For example, the protrusion portion PRT may be located between the first capacitor electrode CPE1 of the first pixel SP1 and the first capacitor electrode CPE1 of the second pixel SP2. The protrusion portion PRT may be spaced apart from each of the first capacitor electrode CPE1 of the first pixel SP1 and the first capacitor electrode CPE1 of the second pixel SP2 in the second direction DR2 by a distance (e.g., a set or predetermined distance).

The shielding electrode SHE may be located on the second metal layer MTL2. The shielding electrode SHE may overlap the first voltage line VDL and may connect the first voltage line VDL. The shielding electrode SHE may extend in the first direction DR1. The shielding electrode SHE may be located between the first pixel SP1 and the second pixel SP2. For example, the shielding electrode SHE may be located between the fourth connection electrode CE4 and the seventh connection electrode CE7.

In the display device 1 according to some embodiments, the protrusion portion PRT and the shielding electrode SHE may receive a voltage having a potential different from those of the first capacitor electrode CPE1 of the first pixel SP1 and the first capacitor electrode CPE1 of the second pixel SP2. Further, the protrusion portion PRT and the shielding electrode SHE may receive a voltage having a potential different from those of the first source electrode SE1 of the first pixel SP1 and the first source electrode SE1 of the second pixel SP2.

Accordingly, the voltage change between the first capacitor electrode CPE1 of the first pixel SP1 and the first capacitor electrode CPE1 of the second pixel SP2 and the voltage change between the first source electrode SE1 of the first pixel SP1 and the first source electrode SE1 of the second pixel SP2 may be shielded, thereby minimizing the coupling phenomenon.

In concluding the detailed description, those skilled in the art will appreciate that many variations and modifications can be made to the disclosed embodiments without substantially departing from the principles of the invention. Therefore, the disclosed embodiments of the invention are used in a generic and descriptive sense only and not for purposes of limitation.

What is claimed is:

1. A display device comprising:
a first pixel and a second pixel, each comprising:
a first transistor comprising a first active region, a first drain electrode, and a first source electrode respectively on one side and an other side of the first active region, and a first gate electrode overlapping the first active region,
a first capacitor electrode connected to the first gate electrode and overlapping the first source electrode, and
a light emitting element connected to the first transistor, wherein
a first end that is one end of the first source electrode of the first pixel, and a second end that is one end of the first source electrode of the second pixel face each other,
a third end that is one end of the first capacitor electrode of the first pixel, and a fourth end that is one end of the first capacitor electrode of the second pixel face each other, and
the first end is between the third end and the fourth end.

2. The display device of claim 1, wherein the second end is between the third end and the fourth end.

3. The display device of claim 1, wherein a distance between the first end and the second end is smaller than a distance between the second end and the third end.

4. The display device of claim 1, wherein a distance between the first end and the second end is smaller than a distance between the first end and the fourth end.

5. The display device of claim 1, wherein a distance between the third end and the fourth end is greater than a distance between the first end and the second end.

6. The display device of claim 1, further comprising a first voltage line connected to the first drain electrode of the first pixel, wherein
the first voltage line comprises a main portion and a protrusion portion protruding from the main portion, and
the protrusion portion is between the first end and the second end.

7. The display device of claim 6, further comprising a shielding electrode connected to the first voltage line,
wherein the shielding electrode is between the first end and the second end.

8. The display device of claim 1, wherein
the light emitting element of the second pixel comprises a first electrode, a light emitting layer on the first electrode, and a second electrode on the light emitting layer, and
the first to fourth ends overlap the first electrode of the second pixel.

9. The display device of claim 8, wherein the first electrode of the second pixel overlaps the first source electrode of the first pixel.

10. The display device of claim 8, wherein the first electrode of the second pixel overlaps the first capacitor electrode of the first pixel.

11. The display device of claim 1, wherein the first capacitor electrode of the first pixel and the first capacitor electrode of the second pixel are adjacent to each other.

12. A display device comprising:
a first pixel and a second pixel, each comprising:
a first transistor comprising a first active region, a first drain electrode, and a first source electrode respectively on one side and an other side of the first active region, and a first gate electrode overlapping the first active region,
a first capacitor electrode connected to the first gate electrode and overlapping the first source electrode, and
a light emitting element connected to the first transistor and comprising a first electrode, a light emitting layer on the first electrode, and a second electrode on the light emitting layer, wherein
a first end that is one end of the first source electrode of the first pixel, a second end that is one end of the first capacitor electrode of the first pixel, and a third end that is one end of the first electrode of the second pixel face one another,
the second end overlaps the first electrode of the second pixel, and
the third end is between the first end and the second end.

13. The display device of claim 12, wherein a distance between the first end and the second end is greater than a distance between the second end and the third end.

14. The display device of claim 12, further comprising a first voltage line connected to the first drain electrode of the first pixel, wherein
the first voltage line comprises a main portion and a protrusion portion protruding from the main portion, and
the protrusion portion is between the first end and the second end.

15. The display device of claim 14, further comprising a shielding electrode connected to the first voltage line, wherein
the shielding electrode is between the first end and the second end.

16. The display device of claim 12, wherein the first electrode of the second pixel overlaps the first source electrode of the first pixel.

17. The display device of claim 12, wherein the first electrode of the second pixel overlaps the first capacitor electrode of the first pixel.

18. The display device of claim 12, wherein the first capacitor electrode of the first pixel and the first capacitor electrode of the second pixel are adjacent to each other.

19. A display device comprising:
a display substrate and a color conversion substrate facing each other; and
a filler between the display substrate and the color conversion substrate,
wherein the display substrate comprises:
a first pixel and a second pixel, each comprising:
a first transistor comprising a first active region, a first drain electrode, and a first source electrode respectively on one side and the other side of the first active region, and a first gate electrode overlapping the first active region,
a first capacitor electrode connected to the first gate electrode and overlapping the first source electrode, and
a light emitting element connected to the first transistor and comprising a first electrode, a light emitting layer on the first electrode, and a second electrode on the light emitting layer, wherein
a first end that is one end of the first source electrode of the first pixel, and a second end that is one end of the first source electrode of the second pixel face each other,
a third end that is one end of the first capacitor electrode of the first pixel, and a fourth end that is one end of the first capacitor electrode of the second pixel face each other, and
the first end is between the third end and the fourth end.

20. The display device of claim 19, wherein
a fifth end that is one end of the first source electrode of the first pixel, a sixth end that is one end of the first capacitor electrode of the first pixel, and a seventh end that is one end of the first electrode of the second pixel face one another,
the sixth end overlaps the first electrode of the second pixel, and
the seventh end is between the fifth end and the sixth end.
